(19) United States
(12) Patent Application Publication
(10) Pub. No.: US 2026/0363153 A1
(43) Pub. Date: Nov. 12, 2026

(54) SEMICONDUCTOR PACKAGE AND METHOD OF MANUFACTURING THE SAME

(71) Applicant: Taiwan Semiconductor Manufacturing Company, Ltd., Hsinchu (TW)

(72) Inventors: Tsu Ching Yang, Taipei (TW); Tzu-Hsiang Hsu, Xinfeng Township (TW); Pin-Cheng Hsu, Zhubei City (TW); Chieh-Fang Chen, Hsinchu County (TW); Katherine H. Chiang, New Taipei City (TW); Chung-Te Lin, Tainan City (TW)

(21) Appl. No.: 19/331,339

(22) Filed: Sep. 17, 2025

Related U.S. Application Data
(60) Provisional application No. 63/801,947, filed on May 8, 2025.

(51) Int. Cl. H10W 99/00; H10B 80/00; H10D 80/30; H10W 72/00; H10W 80/00; H10W 90/00

(52) U.S. Cl. CPC H10W 99/00; H10W 72/019; H10B 80/00; H10D 80/30; H10W 72/01938; H10W 80/211; H10W 80/312; H10W 80/327; H10W 90/00

(57) ABSTRACT

A method of manufacturing a three-dimensional integrated circuit package is provided. The method includes: providing a logic wafer including a front bonding structure along a frontside surface of the logic wafer; forming a first memory wafer including a first sacrificial dielectric layer over a first substrate, a first buried bonding structure over the first sacrificial dielectric layer, and a first front bonding structure along a frontside surface of the first memory wafer; flipping and bonding the first memory wafer to the logic wafer by bonding the first front bonding structure of the first memory wafer to the front bonding structure of the logic wafer; and removing the first substrate and the first sacrificial dielectric layer from the first memory wafer to expose the first buried bonding structure from a backside surface of the first memory wafer.

### REFERENCE T0 RELATED APPLICATION

This Application claims the benefit of U.S. Provisional Application number 63/801,947, filed on May 8, 2025, the contents of which are hereby incorporated by reference in their entirety.

### BACKGROUND

The semiconductor industry has continually improved the processing capabilities and power consumption of integrated circuits (ICs) by shrinking the minimum feature size. However, in recent years, process limitations have made it difficult to continue shrinking the minimum feature size. The stacking of two-dimensional (2D) ICs into three-dimensional (3D) ICs has emerged as a potential approach to continue improving processing capabilities and power consumption of ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic view of a 3D integrated circuit (IC) package including a stack of memory wafers bonded to a logic wafer according to some embodiments of the present disclosure.

FIG. 1B illustrates a schematic view of a plurality of monolithic memory layers in a memory wafer of the stack of memory wafers according to some embodiments of the present disclosure.

FIGS. 1C-1G illustrate schematic views of a plurality of memory types of memory cells in a memory wafer according to some embodiments of the present disclosure.

FIGS. 2-8 are a series of cross-sectional views of intermediate semiconductor structures that illustrate some exemplary steps of a method for manufacturing a 3D IC package including a stack of memory wafers bonded to a logic wafer in FIG. 1A according to some embodiments.

FIG. 9 illustrates a flow diagram of a method of manufacturing a 3D IC package including a stack of memory wafers bonded to a logic wafer in FIG. 1A according to some embodiments.

FIGS. 10-15 are a series of cross-sectional views of intermediate semiconductor structures that illustrate some exemplary steps of a method for manufacturing an intermediate memory wafer including a buried bonding structure over a sacrificial dielectric that is arranged over a semiconductor substrate according to some embodiments.

FIG. 16 illustrates a flow diagram of a method of manufacturing an intermediate memory wafer including a buried bonding structure over a sacrificial dielectric that is arranged over a semiconductor substrate according to some embodiments.

FIG. 17 illustrates a schematic view of a 3D integrated circuit (IC) package including a stack of memory wafers bonded to a logic wafer according to other embodiments of the present disclosure.

FIGS. 18-26 are a series of cross-sectional views of intermediate semiconductor structures that illustrate some exemplary steps of a method for manufacturing a 3D IC package including a stack of memory wafers bonded to a logic wafer in FIG. 17 according to some embodiments.

FIG. 27 illustrates a flow diagram of a method of manufacturing a 3D IC package including a stack of memory wafers bonded to a logic wafer in FIG. 17 according to some embodiments.

FIG. 28A and FIG. 28B respectively are a schematic view and a cross-sectional view illustrating a memory wafer and a base logic wafer bonded to each other according to some embodiments.

FIG. 29A and FIG. 29B respectively are a schematic view and a cross-sectional view illustrating a memory wafer and a base logic wafer bonded to each other, with a substrate and a sacrificial dielectric layer of the memory wafer removed therefrom, according to some embodiments.

FIG. 30 is a top view of a memory wafer illustrating laser spots in various zones according to some embodiments.

FIGS. 31-39 are a series of cross-sectional views of intermediate semiconductor structures that illustrate some exemplary steps of a method for manufacturing a 3D IC package including a stack of memory wafers bonded to a logic wafer according to still other embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, and the like, may be used herein for ease of description to describe one element or feature's relationship to another element(s) or feature(s) as illustrated in the figures. The spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may likewise be interpreted accordingly. Even more, the terms “first”, “second”, “third”, “fourth”, and the like are merely generic identifiers and, as such, may be interchanged in various embodiments. For example, while an element (e.g., a conductive wire) may be referred to as a “first” element in some embodiments, the element may be referred to as a “second” element in other embodiments.

Memory devices such as various types of Dynamic Random-Access Memories (DRAMs) are widely used nowadays. For example, a high bandwidth memory (HBM) is a type of memory architecture that stacks multiple DRAM wafers on top of one another to create a high-bandwidth and high-capacity memory solution, allowing for faster data transfer and increased memory density compared to traditional memory architectures. A DRAM wafer may have a plurality of front-end-of-line (FEOL) DRAM cells, and a plurality of FEOL logic circuits, such as local sensing amplifiers (SAs) and local word line (WL) drivers. Shrinkage of a DRAM wafer is thus limited not only by the DRAM cells within the DRAM wafer but also by the FEOL logic circuits within the DRAM wafer. There is a continuous need to improve space efficiency, control thermal budget, reduce and/or simplify manufacturing steps, and shorten manufacturing period of HBM products.

In view of the forgoing, in accordance with the present disclosure, in some embodiments, a method of manufacturing a three-dimensional integrated circuit package is provided. The method includes providing a logic wafer comprising a bonding structure along a frontside surface of the logic wafer and coupled to a logic device within the logic wafer; forming a first memory wafer comprising a first sacrificial dielectric layer over a first substrate, a first buried bonding structure over the first sacrificial dielectric layer, and a first front bonding structure along a frontside surface of the first memory wafer; flipping and bonding the first memory wafer to the logic wafer by bonding the first front bonding structure of the first memory wafer to the front bonding structure of the logic wafer; and removing the first substrate and the first sacrificial dielectric layer from the first memory wafer to expose the first buried bonding structure from a backside surface of the first memory wafer. In some embodiments, the first substrate and the first sacrificial dielectric layer are removed from the first memory wafer by employing at least a laser lift-off process.

In other embodiments, a method of manufacturing a three-dimensional integrated circuit package is provided. The method includes providing a first memory wafer comprising a first sacrificial dielectric layer over a first substrate; forming a first etch stop layer on the first sacrificial dielectric layer; forming a first buried dielectric layer on the first etch stop layer; forming a plurality of first buried bonding conductors embedded within the first buried bonding dielectric layer to create a first buried bonding structure; forming a first interlayer dielectric (ILD) layer over the first buried bonding structure; and forming a first front bonding structure along a frontside surface of the first memory wafer, in which the first front bonding structure includes a first front bonding dielectric layer over the first buried bonding dielectric layer and a plurality of first front bonding conductors embedded within the first front bonding dielectric layer. In some embodiments, the method further includes flipping and bonding the first memory wafer to a logic wafer; and removing the first semiconductor substrate and the first sacrificial dielectric layer from the first memory wafer.

In yet other embodiments, a method of manufacturing a three-dimensional integrated circuit package is provided. The method includes providing a first memory wafer comprising a first sacrificial dielectric layer over a first substrate; forming a first buried bonding structure over the first sacrificial dielectric layer within ILD; forming a first pair of redistribution layers (RDLs) over the first buried bonding structure, the first pair of RDLs comprising a first RDL and a second RDL over the first RDL; forming a second sacrificial dielectric layer over the first pair of RDLs; forming a second substrate over the second sacrificial dielectric layer; flipping the first memory wafer and removing the first substrate and the first sacrificial dielectric layer from the first memory wafer to expose the first buried bonding structure; flipping the first memory wafer and bonding the first memory wafer to a base wafer comprising a bonding structure along a frontside surface thereof, wherein the first buried bonding structure of the first memory wafer is bonded to the bonding structure of the base wafer; removing the second substrate and the second sacrificial dielectric layer from the second memory wafer to expose the second RDL; and forming a first front bonding structure over and coupled to the second RDL along a frontside surface of the first memory wafer.

In this way, an improved method for manufacturing an integrated circuit package including multiple stacked “BEOL-only” memory wafers and a logic base wafer is provided. The multiple “BEOL-only” memory wafers can be free of front-end-of-line (FEOL) components, since all FEOL components can be integrated into the underlying logic base wafer. Such “BEOL-only” memory wafers can be used in for example artificial intelligence (AI) applications, in which high integration density and capacity are essential. The buried bonding structure of a memory wafer of the memory wafers can be vertically attached to another memory wafer or the logic wafer, and additionally a laser lift-off technique can be used to remove the substrate and the sacrificial dielectric layer of the memory wafer to expose the buried bonding structure thereof, thereby advantageously providing enhanced design flexibility, simplifying the process flow of forming the bonding structures of the memory wafers, reducing defect source and wafer broken risk by getting rid of a wafer BS silicon grinding process that may need extra wafer edge engineering process like edge sealing, edge trim, and dry/wet clean, and obtaining well-controlled surface roughness and thermal budget to improve product yield and device performance.

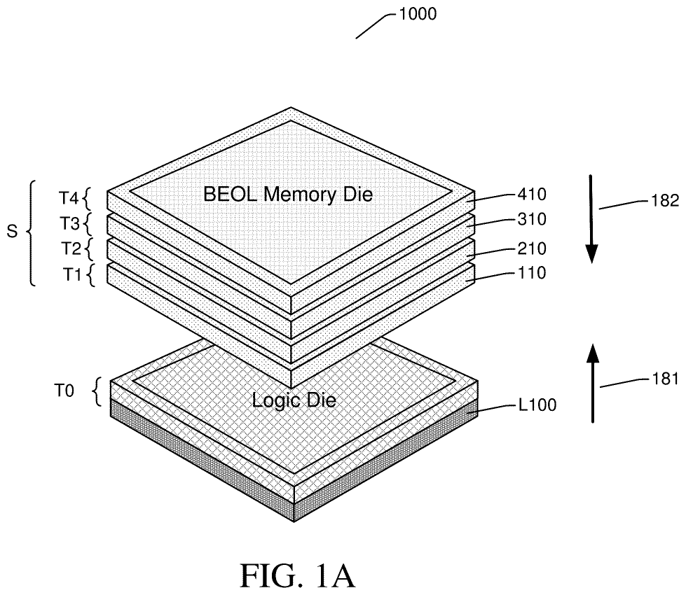

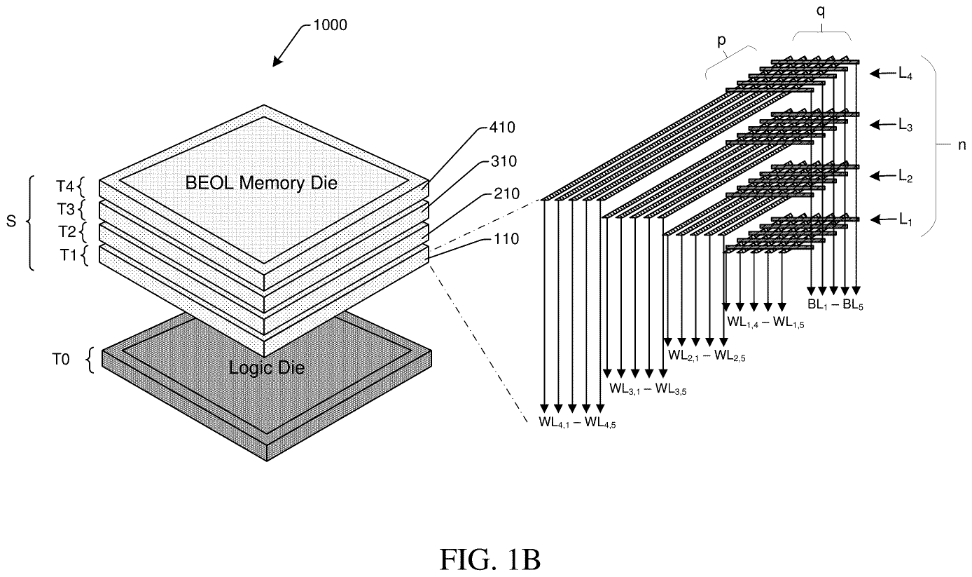

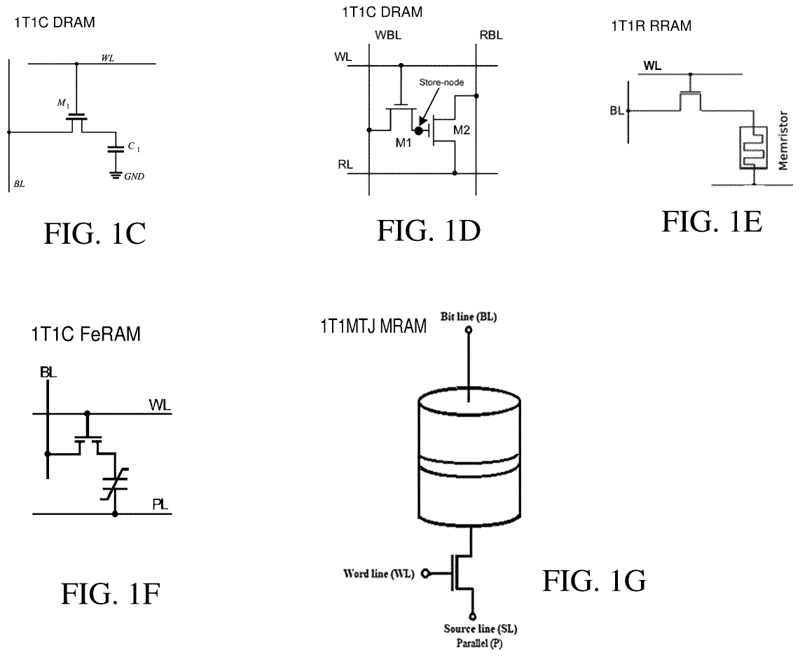

FIG. 1A illustrates a schematic view of a 3D integrated circuit (IC) package 1000 including a logic wafer and a stack of memory wafers bonded to the logic wafer according to various embodiments of the present disclosure. In some embodiments, the IC package 1000 includes a logic wafer T0 including a substrate L100, and a stack S of memory wafers (e.g., T1, T2, T3, and T4) bonded to the logic wafer T0. As shown in FIG. 1A, the stack S of memory wafers includes a first memory wafer T1, absent a substrate, having a first interlayer dielectric (ILD) 110, and bonded to the logic wafer TL; a second memory wafer T2, absent a substrate, having a second ILD 210, and bonded to the first memory wafer T1; a third memory wafer T3, absent a substrate, having a third ILD 310, and bonded to the second memory wafer T2; and a fourth memory wafer T4, absent a substrate, having a fourth ILD 410, and bonded to the third memory wafer T3. In some embodiments, the logic wafer T0 stands in an original upright orientation 181, while the memory wafers (e.g., T1, T2, T3 and T4) in the stack S all stand in a flipped orientation 182 opposite to the upright orientation 181. Although embodiments herein are described with respect to wafer-to-wafer bonding, it should be appreciated that die-to-die bonding or die-to-wafer bonding may be used in place of wafer-to-wafer bonding, and the claimed disclosure is not limited thereto.

In some embodiments, none of the memory wafers (e.g., T1, T2, T3 and T4) in the stack S as shown in FIG. 1A includes a logic device therein. In some embodiments, none of the memory wafers (e.g., T1, T2, T3 and T4) in the stack S as shown in FIG. 1A includes a substrate therein, while in other embodiments, only a topmost memory wafer (e.g., T4) of the memory wafers (e.g., T1, T2, T3 and T4) in the stack S as shown in FIG. 1A includes a substrate (not shown).

Although four memory wafers are illustrated to be stacked in the stack S of memory wafers (e.g., T1, T2, T3 and T4) in FIG. 1A, any multiple number m of memory wafers (such as T1-Tm) can be stacked on top of one another and bonded to one another without going beyond the scope of the present disclosure. In some embodiments, the multiple number m is in a range from 2 to 8, while in other embodiments, the multiple number m is in a range from 3 to 6. The number and the sequence of memory wafers in the stack of memory wafers can be adjusted based on the product requirement to satisfy different product application, for example, to improve throughput and control thermal budget to every layer.

FIG. 1B illustrates a schematic view of a plurality of monolithic memory layers in a memory wafer (e.g., T1) of the stack S of memory wafers (e.g., T1, T2, T3 and T4) according to some embodiments of the present disclosure. In some embodiments, each memory wafer in a stack S of memory wafers includes a multiple number n (e.g., n=4) of memory layers. For example, as shown in FIG. 1B, the first ILD 110 of the first memory wafer T1 includes four memory layers or tiers (such as L1, L2, L3 and L4). In some embodiments, each memory layer (e.g., L1) of the memory layers can be used to dispose an array of memory cells arranged in a multiple number p rows and a multiple number q columns, and thus each memory layer of the memory layers can include a multiple number p×q of memory cells. Accordingly, the stack S of multiple number m of memory wafers (such as T1-Tm) can include a total number m×n×p×q of memory cells that are disposed in a total number m×n of memory layers. As such, a total height or thickness of the stack of memory wafers is greatly reduced at least due to each memory wafer being absent of a substrate and each memory wafer having no logic devices therein, a density solution of the memory cells in the stack of memory wafers is greatly increased due to each memory wafer not being used by any logic device, and thus advantageously leading to improved performance of the stack of memory wafers, which can be used as in an HBM product (e.g., for artificial intelligence applications).

FIGS. 1C-1G illustrate schematic views of some exemplary memory types of memory cells in a memory wafer of the stack S of memory wafers in FIG. 1A according to some embodiments of the present disclosure. In some embodiments, a memory cell in a memory wafer of the stack S of memory wafers can be, for example, a 1-Transistor 1-Capacitor (1T1C) Dynamic Random Access Memory (DRAM), a 2T (2-Transistor) DRAM, a 1-Transistor 1-Resistor (1T1R) Resistive Random Access Memory (RRAM), a 1T1C Ferroelectric Random Access Memory (FeRAM), or a 1-Transistor 1-Magnetic Tunnel Junction (1TIMTJ) Magnetoresistive Random Access Memory (MRAM), and the like.

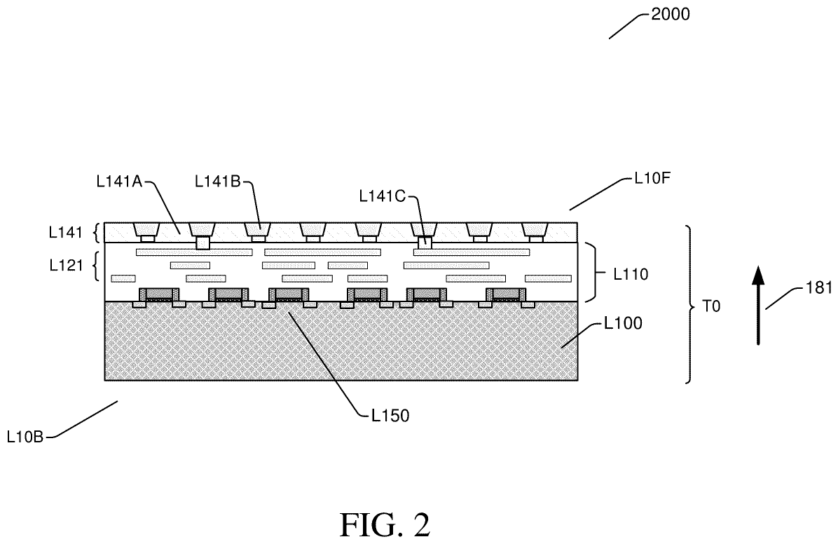

FIGS. 2-8 are a series of cross-sectional views of intermediate semiconductor structures that illustrate some exemplary steps of a method for manufacturing a 3D IC package 1000 including a stack S of memory wafers (e.g., T1, T2, T3 . . . ) bonded to a logic wafer T0 in FIG. 1A according to some embodiments. Although FIGS. 2-8 are described in relation to a method, it will be appreciated that the structures disclosed in FIGS. 2-8 are not limited to such a method, but instead may stand alone as structures independent of the method.

As shown in the cross-sectional view 2000 of FIG. 2, a base logic wafer T0 is provided. In some embodiments, the base logic wafer T0 includes a substrate L100, one or more logic devices L150 (such as a sense amplifier, a row decode circuit, a write circuit, a read control circuit, and a computation circuit) in a front-end-of-line (FEOL) arranged along a frontside surface L10F of the substrate L100, an ILD L110 over substrate L100, a redistribution layer (RDL) L121 within the ILD L110 and over the logic devices L150, and a front bonding structure L141 along a frontside surface L10F of the base logic wafer T0. In some embodiments, the front bonding structure L141 of the base logic wafer T0 includes a dielectric bonding layer L141A, multiple conductive bonding pads L141B along the frontside surface L10F of the logic wafer T0, and multiple conductive bonding contacts L141C to couple the multiple conductive bonding pads L141B to the RDL L121.

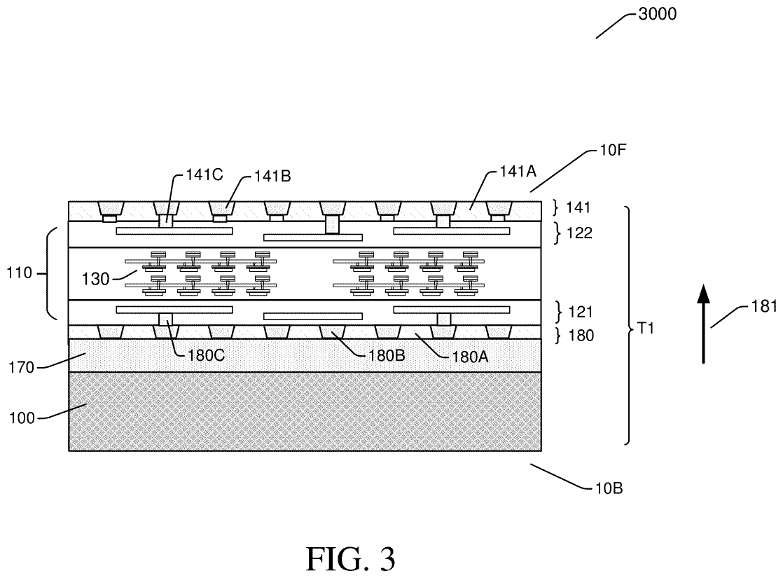

As shown in the cross-sectional view 3000 of FIG. 3, a first memory wafer T1 is provided and stands in an original upright orientation 181. In some embodiments, the first memory wafer T1 includes a first substrate 100, a first sacrificial dielectric layer 170 disposed over the first substrate 100, a first buried bonding structure 180 disposed over the first sacrificial dielectric layer 170, a first ILD 110 disposed over the first buried bonding structure 180, a first pair of RDLs 121 and 122 disposed within the first ILD 110, multiple layers of first memory cells 130 disposed vertically between the first pair of RDLs 121 and 122, and a first front bonding structure 141 disposed along a frontside surface 10F of the first memory wafer T1. In some embodiments, the first front bonding structure 141 includes a first front dielectric bonding layer 141A, one or more first front conductive bonding pads 141B along the frontside surface 10F of the first memory wafer T1, and one or more first front conductive bonding contacts 141C to couple the one or more first front conductive bonding pads 141B to the adjacent second RDL 122.

In some embodiments, the first buried bonding structure 180 includes a first buried dielectric bonding layer 180A along a top surface of the first sacrificial dielectric layer 170, one or more first buried conductive bonding pads 180B embedded within first buried dielectric bonding layer 180A, and one or more first conductive bonding contacts 180C embedded within the first ILD 110 to couple the one or more first conductive bonding pads 180B to the adjacent first RDL 121.

In some embodiments, the first substrate 100 includes a semiconductor material selected from silicon, SiC, GaAs, GaN, Ge, Al₂O₃, InP, or synthetic. In some embodiments, the first sacrificial dielectric layer 170 includes silicon oxide, such as SiO₂. In some embodiments, the first buried dielectric bonding layer 180A includes a dielectric material, such as SiO₂. In some embodiments, the one or more first conductive bonding pads 180B includes a conductive material, such as copper (Cu), copper alloy (e.g., Cu—Mn), Nickel (Ni), Gold (Au).

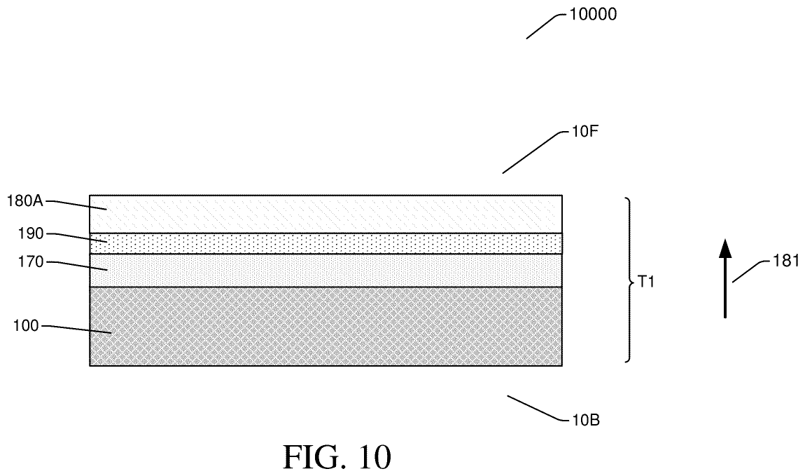

The formation of a memory wafer (e.g., a memory die T1) including a buried bonding structure (e.g., a first buried bonding structure 180) over a sacrificial dielectric (e.g., a first sacrificial dielectric layer 170) as shown in FIG. 3 will be explained in more details later with respect to FIGS. 10-15.

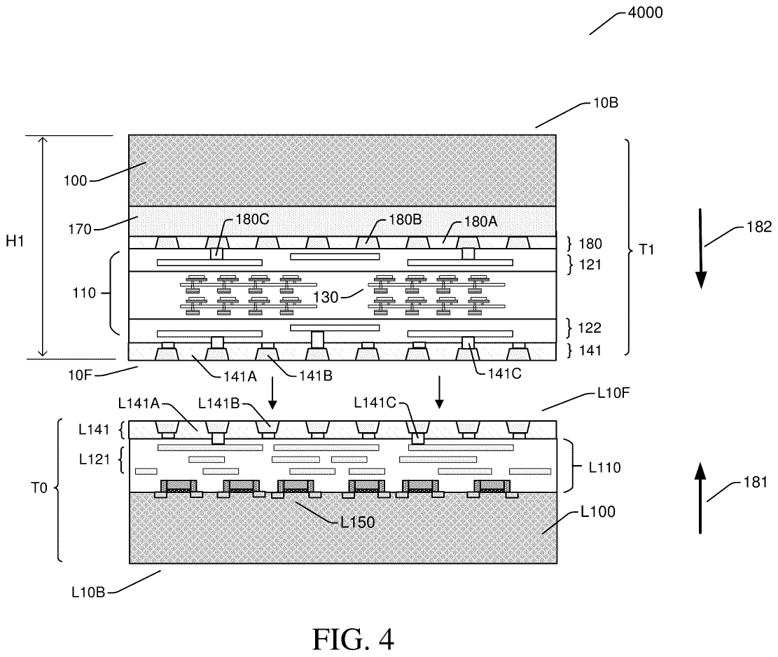

As shown in the cross-sectional view 4000 of FIG. 4, the first memory wafer T1 in FIG. 3 is flipped, and thus stands in a flipped orientation 182. Then, the flipped first memory wafer T1 is bonded to the base logic wafer T0 that stands in the upright orientation 181. In some embodiments, the first front dielectric bonding layer 141A of the first front bonding structure 141 of the first memory wafer T1 is bonded to the dielectric bonding layer L141A of the front bonding structure L141 of the base logic wafer T0, and the multiple first front conductive bonding pads 141B of the first front bonding structure 141 of the first memory wafer T1 are bonded to the multiple conductive bonding pads L141B of the front bonding structure L141 of the base logic wafer T0. Thus, the first memory wafer T1 is face-to-face bonded to the base logic wafer T0 by the first front bonding structure 141 of the first memory wafer T1 and the front bonding structure L141 of the base logic wafer T0. In some embodiments, the height or thickness H1 of the first memory wafer T1 is in a range from 740 to 780 um.

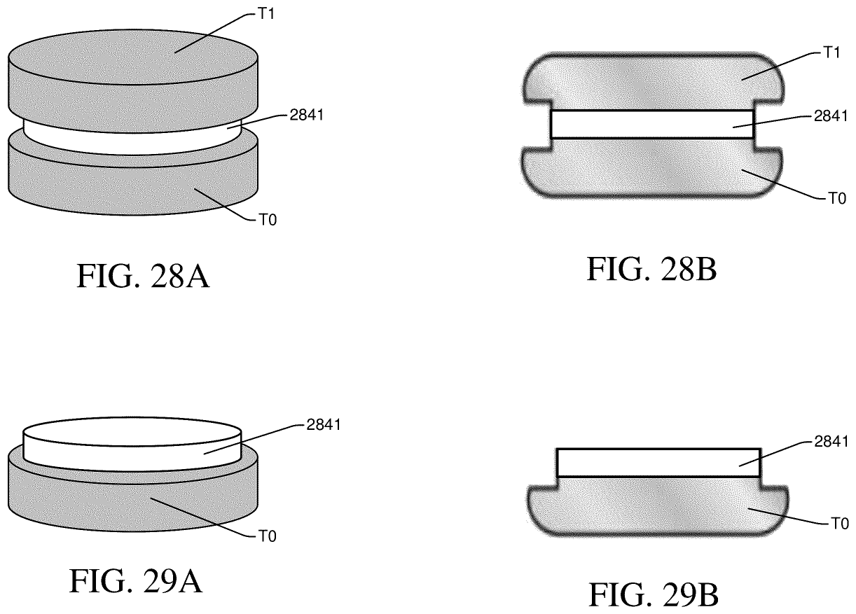

FIGS. 28A and 28B respectively are a schematic view and a cross-sectional view illustrating a first memory wafer T1 and a base logic wafer T0 face-to-face bonded to each other by a bonding structure included in a portion 2841 according to some embodiments. In some embodiments, the bonding structure is a combination of the first front bonding structure 141 of the first memory wafer T1 and the front bonding structure L141 of the base logic wafer T0 as shown in FIG. 4.

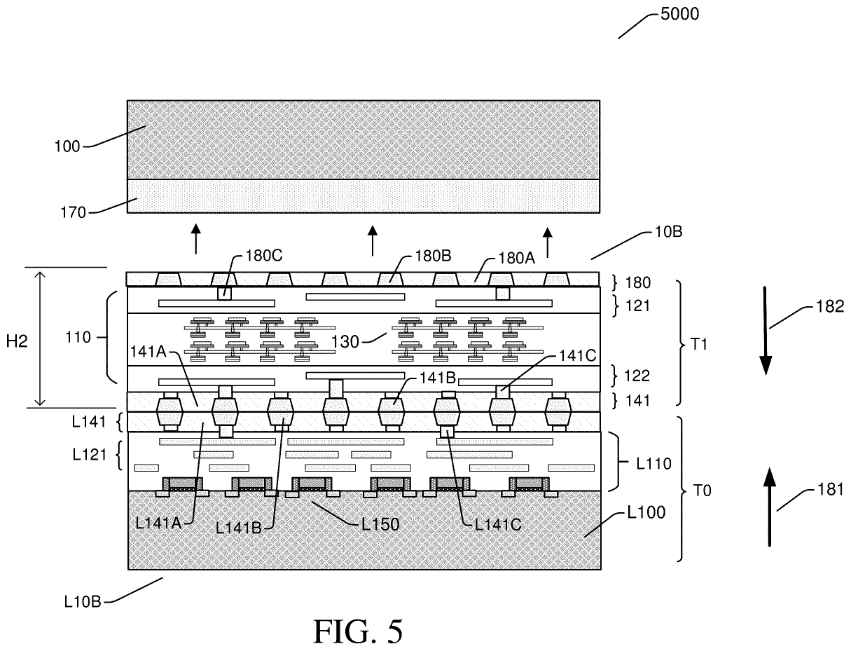

As shown in the cross-sectional view 5000 of FIG. 5, the first substrate 100 and the first sacrificial dielectric layer 170 are removed and thus the first buried bonding structure 180 is exposed from the backside surface 10B of the first memory wafer T1. In some embodiments, after the first substrate 100 and the first sacrificial dielectric layer 170 are removed from the first memory wafer T1, the height or thickness H2 of the first memory wafer T1 is greatly reduced and is in a range from 3 to 6 um.

In some embodiments, the first substrate 100 and the first sacrificial dielectric layer 170 are removed by employing a laser lift-off process based on the principle of using the difference in the coefficient of thermal expansion (CTE) between the two materials of the first substrate 100 and the first sacrificial dielectric layer 170. The laser lift-off process works by utilizing, for example, laser absorption, silicon melting or vaporization, thermal Expansion difference, stress build-up, and lift-off. Laser absorption is used for example. A high-power laser (e.g., excimer, Nd: YAG, or DPSS laser) is used to irradiate the silicon substrate through the transparent oxide layer. The laser wavelength is chosen so that it is absorbed by the silicon, but not significantly by the oxide layer. Silicon melting or vaporization is also used for example. The absorbed laser energy rapidly heats the silicon, causing it to melt or even vaporize. Thermal expansion difference is also used for example. Silicon and silicon dioxide (thermal oxide) have different CTEs. Specifically, the CTE of silicon (around 2.5-2.6×10⁻⁶/K) is higher than that of silicon dioxide (around 0.24-0.5×10⁻⁶/K). Stress build-up is also used for example. As the silicon heats and expands due to the laser irradiation, the oxide layer expands at a much slower rate due to its lower CTE. This difference in expansion creates significant stress at the interface between the silicon and the oxide layer thereover. Lift-off is thus realized for example. The accumulated stress, coupled with the vapor pressure from the melted or vaporized silicon, causes the oxide layer to detach from the silicon substrate, lifting it off the surface thereof. As such, the first substrate and the first sacrificial dielectric layer can be simply and cleanly removed by employing the laser lift-off process with single-shot laser pulses for example, and thus defect source and wafer broken risk are advantageously reduced by getting rid of a wafer BS silicon grinding process.

FIGS. 29A and 29B respectively are a schematic view and a cross-sectional view illustrating the first memory wafer T1 and the base logic wafer T0 bonded to each other with a substrate (e.g., 100 in FIG. 5) and a sacrificial dielectric layer (e.g., 170 in FIG. 5) of the first memory wafer T1 removed therefrom according to some embodiments.

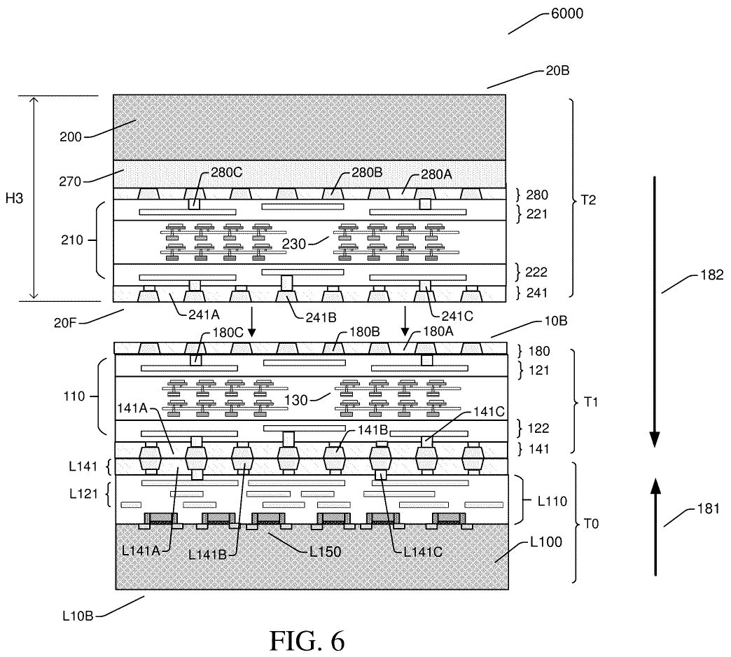

As shown in the cross-sectional view 6000 of FIG. 6, a second memory wafer T2 is provided and flipped. The second memory wafer T2 is similar to the first memory wafer T1. In some embodiments, the second memory wafer T2 includes a second substrate 200, a second sacrificial dielectric layer 270 disposed over the second substrate 200, a second buried bonding structure 280 disposed over the second sacrificial dielectric layer 270, a second ILD 210 disposed over the second buried bonding structure 280, a second pair of RDLs 221 and 222 disposed within the second ILD 210, multiple layers of second memory cells 230 disposed vertically between the second pair of RDLs 221 and 222, and a second front bonding structure 241 disposed along a frontside surface 20F of the second memory wafer T2. In some embodiments, the second front bonding structure 241 of the second memory wafer T2 includes a second front dielectric bonding layer 241A, one or more second front conductive bonding pads 241B along the frontside surface 20F of the second memory wafer T2, and one or more second front conductive bonding contacts 241C to couple the one or more second front conductive bonding pads 241B to the adjacent RDL 222. In some embodiments, the height or thickness H3 of the second memory wafer T2 is in a range from 740 to 780 um.

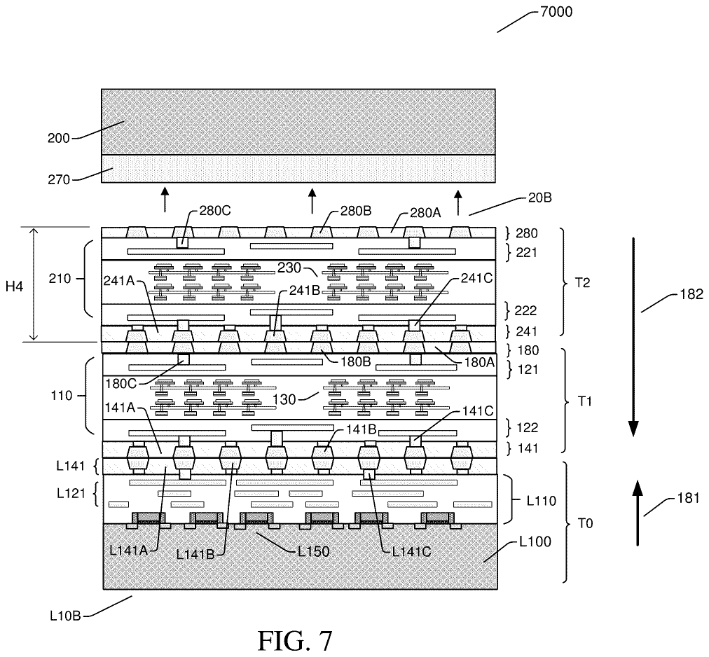

As shown in the cross-sectional view 7000 of FIG. 7, the flipped second memory wafer T2 is bonded to the flipped first memory wafer T1, and then the second substrate 200 and the second sacrificial dielectric layer 270 are removed by employing a laser lift-off process to expose the second buried bonding structure 280 along the backside surface 20B of the second memory wafer T2. In some embodiments, after the second substrate 200 and the second sacrificial dielectric layer 270 are removed from the second memory wafer T2, the height or thickness H4 of the second memory wafer T2 is greatly reduced and is in a range from 3 to 6 um.

In some embodiments, the second front dielectric bonding layer 241A of the second front bonding structure 241 of the second memory wafer T2 is bonded to the first buried dielectric bonding layer 180A of the first buried bonding structure 180 of the first memory wafer T1, and the multiple second front conductive bonding pads 241B of the second front bonding structure 241 of the second memory wafer T2 is bonded to the multiple first conductive bonding pads 180B of the first buried bonding structure 180 of the first memory wafer T1. As such, the second memory wafer T2 is face-to-bottom bonded to the first memory wafer T1.

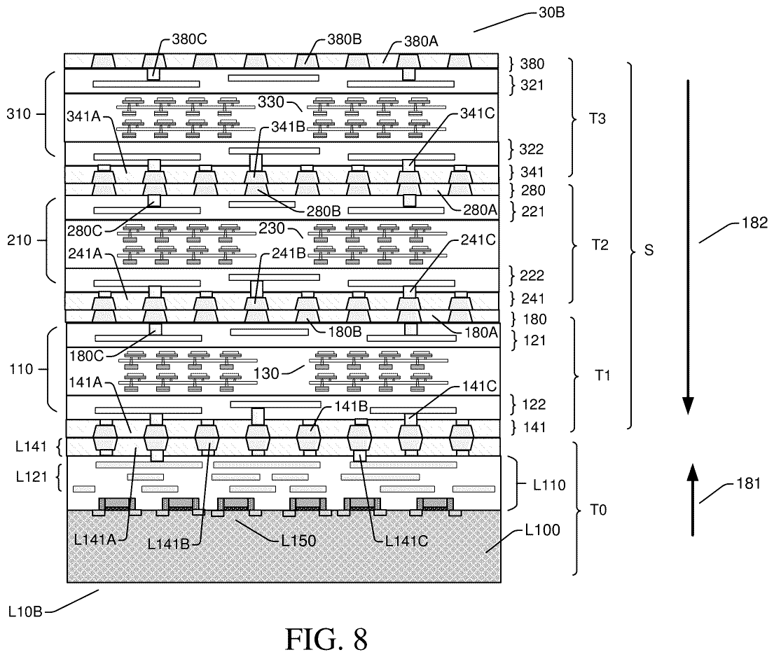

As shown in the cross-sectional view 8000 of FIG. 8, a stack S of flipped memory wafers T1-T3 are face-to-bottom stacked and bonded to the base logic wafer T0. In some embodiments, as shown in FIG. 8, none of the memory wafers (e.g., T1, T2 and T3) in the stack S includes a substrate therein, while in other embodiments, only a topmost memory wafer (e.g., T3) of the memory wafers (e.g., T1, T2 and T3) in the stack S includes a substrate (not shown). In some embodiments, none of the memory wafers (e.g., T1, T2 and T3) in the stack S includes a logic device therein.

In this way, an integrated circuit package that includes a stack of multiple “BEOL-only” (free of FEOL components) memory wafers bonded to a base logic wafer is manufactured. Each of the memory wafers includes, among other things, a buried bonding structure that is covered by a substrate and a sacrificial dielectric layer, which will be removed later by employing a laser lift-off technique to expose the buried bonding structure for bonding to an additional memory wafer, thereby advantageously providing enhanced design flexibility and simplifying the process flow of forming the bonding structures of the memory wafers.

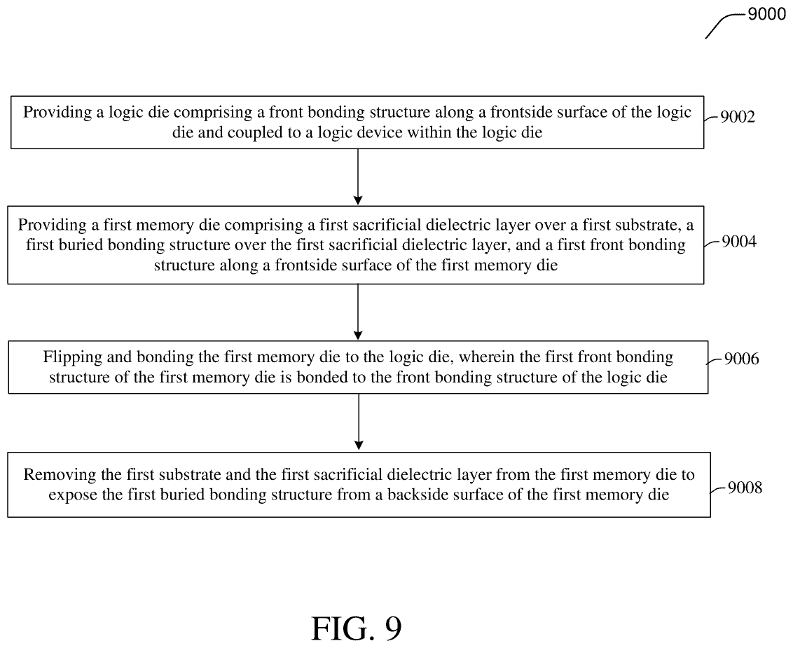

FIG. 9 illustrates a flow diagram of a method of manufacturing a 3D IC package including a stack of memory wafers bonded to a logic wafer in FIG. 8 according to some embodiments. _ It should be noted that the method 9000 is merely an example, and is not intended to limit the present disclosure. Accordingly, it is understood that the order of operations of the method 9000 of FIG. 9 can be changed, additional operations can be provided before, during, and after the method 9000 of FIG. 9, and other operations may be described briefly herein.

Referring to FIGS. 2 and 9, the method 9000 starts with operation 9002 of providing a base logic wafer T0 including a front bonding structure L141 along a frontside surface L10F of the base logic wafer T0 and coupled to at least one logic device L150 within the base logic wafer T0. In some embodiments, the front bonding structure L141 of the base logic wafer T0 includes a dielectric bonding layer L141A, multiple conductive bonding pads L141B along the frontside surface L10F of the logic wafer T0, and multiple conductive bonding contacts L141C to couple the multiple conductive bonding pads L141B to the RDL L121.

Referring to FIGS. 3 and 9, the method 9000 also includes operation 9004 of forming a first memory wafer T1 including a first sacrificial dielectric layer 170 arranged over a first substrate 100, a first buried bonding structure 180 arranged over the first sacrificial dielectric layer 170, and a first front bonding structure 141 along a frontside surface 10F of the first memory wafer T1. In some embodiments, the first memory wafer T1 also includes a first ILD 110 disposed over the first buried bonding structure 180, a first pair of RDLs 121 and 122 disposed within the first ILD 110, and multiple layers of first memory cells 130 disposed vertically between the first pair of RDLs 121 and 122. In some embodiments, the first front bonding structure 141 is disposed over and coupled to the adjacent second RDL 122. In some embodiments, the first front bonding structure 141 includes a first front dielectric bonding layer 141A, one or more first front conductive bonding pads 141B along the frontside surface 10F of the first memory wafer T1, and one or more first front conductive bonding contacts 141C to couple the one or more first front conductive bonding pads 141B to the adjacent second RDL 122.

Next, referring to FIGS. 4 and 9, the method 9000 proceeds to operation 9006 of flipping and bonding the first memory wafer T1 to the base logic wafer T0, in which the first front bonding structure 141 of the first memory wafer T1 is bonded to the front bonding structure L141 of the base logic wafer T0. In some embodiments, the first front dielectric bonding layer 141A of the first front bonding structure 141 of the first memory wafer T1 is bonded to the dielectric bonding layer L141A of the front bonding structure L141 of the base logic wafer T0, and the multiple first front conductive bonding pads 141B of the first front bonding structure 141 of the first memory wafer T1 are bonded to the multiple conductive bonding pads L141B of the front bonding structure L141 of the base logic wafer T0. Thus, the first memory wafer T1 is face-to-face bonded to the base logic wafer T0.

Next, referring to FIGS. 5 and 9, the method 9000 proceeds to operation 9008 of removing the first substrate 100 and the first sacrificial dielectric layer 170 from the first memory wafer T1 to expose the first buried bonding structure 180 along a backside surface 10B of the first memory wafer T1. In some embodiments, the first substrate 100 and the first sacrificial dielectric layer 170 are removed by employing a laser lift-off process. In some embodiments, after the first substrate 100 and the first sacrificial dielectric layer 170 are removed from the first memory wafer T1, the height or thickness H2 of the first memory wafer T1 is greatly reduced and is in a range from 3 to 6 um.

Next, as shown in FIGS. 6-7, a second memory wafer T2 is provided, flipped, and bonded to the first memory wafer T1, in which the second front dielectric bonding layer 241A of the second front bonding structure 241 of the second memory wafer T2 is bonded to the first buried dielectric bonding layer 180A of the first buried bonding structure 180 of the first memory wafer T1, and the multiple second front conductive bonding pads 241B of the second front bonding structure 241 of the second memory wafer T2 is bonded to the multiple first conductive bonding pads 180B of the first buried bonding structure 180 of the first memory wafer T1. As such, the second memory wafer T2 is face-to-bottom bonded to the first memory wafer T1.

After that, as shown in FIG. 8, in the same way, a third memory wafer T3 is provided, flipped, and bonded to the second memory wafer T2, in which the third front dielectric bonding layer 341A of the third front bonding structure 341 of the third memory wafer T3 is bonded to the second buried dielectric bonding layer 280A of the second buried bonding structure 280 of the second memory wafer T2, and the multiple third front conductive bonding pads 341B of the third front bonding structure 341 of the third memory wafer T3 is bonded to the multiple second conductive bonding pads 280B of the second buried bonding structure 280 of the second memory wafer T2. These processes can be repeated, and thus multiple (such as T2-T10) memory wafers can be stacked on one another and bonded to the base logic wafer T0.

In this way, a buried bonding structure in each of multiple memory wafers is removed by employing a laser lift-off technique to expose the buried bonding structure for bonding to an additional memory wafer, thereby advantageously providing enhanced design flexibility, simplifying the process flow of forming the bonding structures of the memory wafers, reducing defect source and wafer broken risk, and obtaining well-controlled surface roughness and thermal budget to improve product yield and device performance.

FIGS. 10-15 are a series of cross-sectional views of intermediate semiconductor structures that illustrate some exemplary steps of a method for manufacturing an intermediate memory wafer (e.g., T1) including a buried bonding structure over a sacrificial dielectric that is arranged over a semiconductor substrate according to some embodiments. Although FIGS. 10-15 are described in relation to a method, it will be appreciated that the structures disclosed in FIGS. 10-15 are not limited to such a method, but instead may stand alone as structures independent of the method.

As shown in the cross-sectional view 10000 of FIG. 10, a first memory wafer T1 is provided and stands in an original upright orientation 181. In some embodiments, the first memory wafer T1 includes a first substrate 100, a first sacrificial dielectric layer 170 disposed over the first substrate 100, an etch stop layer 190 disposed over the first sacrificial dielectric layer 170, and a first buried dielectric bonding layer 180A disposed over the etch stop layer 190.

In some embodiments, the first substrate 100 includes a semiconductor material selected from silicon, SiC, GaAs, GaN, Ge, Al₂O₃, InP, or synthetic. In some embodiments, the first sacrificial dielectric layer 170 includes silicon oxide, such as SiO₂. In some embodiments, the first buried dielectric bonding layer 180A includes a dielectric material, such as SiO₂. In some embodiments, the one or more first conductive bonding pads 180B includes a conductive material, such as copper (Cu), copper alloy (e.g., Cu—Mn), Nickel (Ni), Gold (Au). In some embodiments, the etch stop layer 190 includes a material selected from Silicon Nitride (Si₃N₄), Titanium Nitride (TiN), or Aluminum Oxide (Al₂O₃).

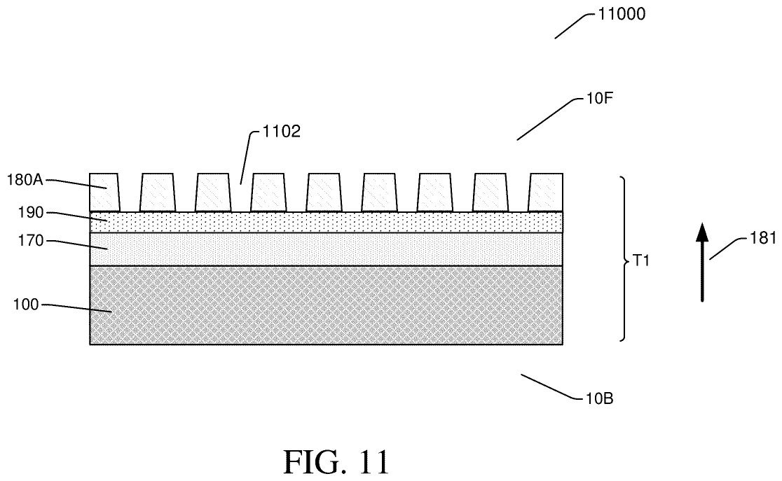

As shown in the cross-sectional view 11000 of FIG. 11, multiple openings 1102 are formed through the first buried dielectric bonding layer 180A and stop at the top surface of the etch stop layer 190 by employing for example photolithography and etching processes. In some embodiments, the multiple openings 1102 exhibit funnel-shaped profiles, each opening 1102 has inwardly tapered sidewalls extending from the top surface thereof to the bottom surface thereof.

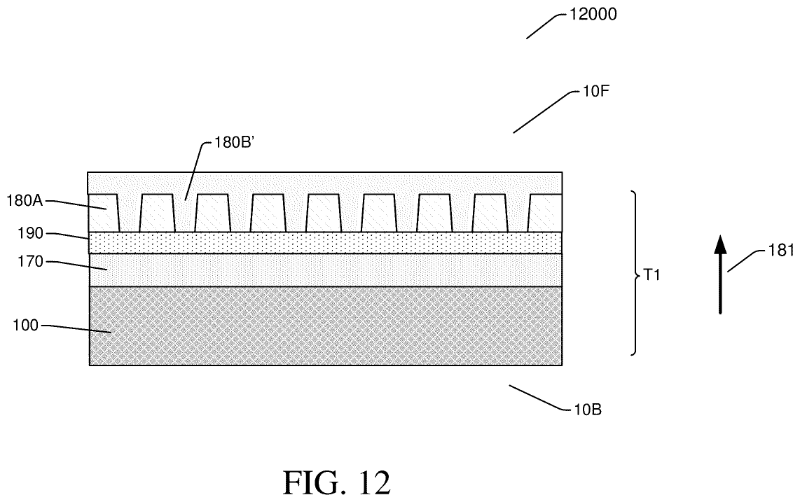

As shown in the cross-sectional view 12000 of FIG. 12, a conductive material 180B′ is filled into the multiple openings 1102 in FIG. 11 by employing for example a deposition (such as CVD and PVD) process. In some embodiments, the conductive material 180B′ includes.

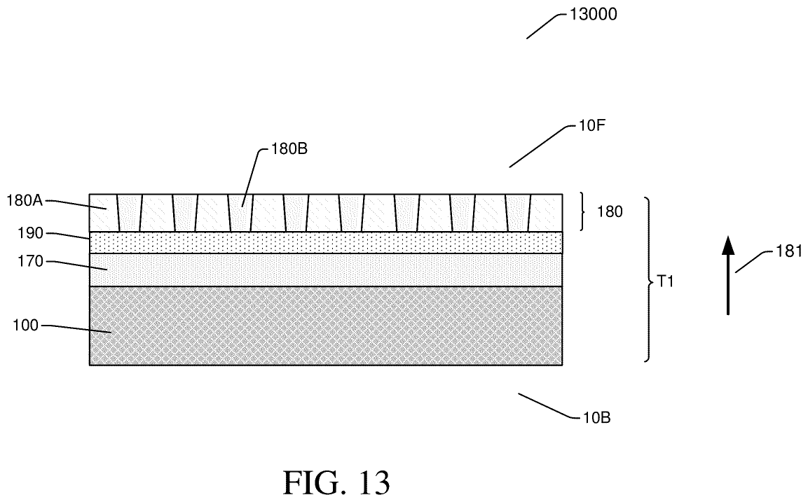

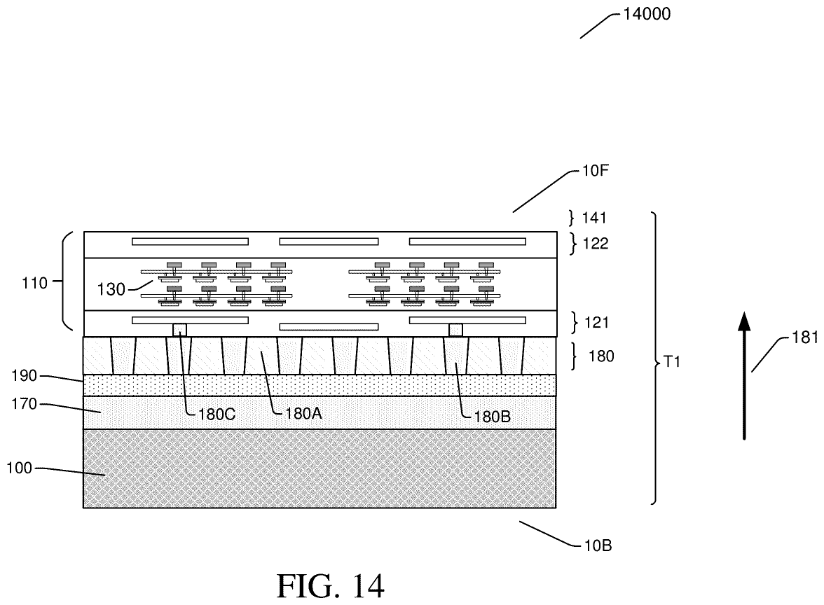

As shown in the cross-sectional view 13000 of FIG. 13, excessive conductive material 180B′ (in FIG. 12) beyond the plurality of openings 1102 (in FIG. 11) is removed by employing, for example, a CMP process, thereby forming multiple first conductive bonding pads 180B. In some embodiments, the first buried dielectric bonding layer 180A and the multiple first conductive bonding pads 180B combinedly form a first buried bonding structure 180 of the first memory wafer T1. In some embodiments, the multiple first conductive bonding pads 180B exhibit funnel-shaped profiles, each first conductive bonding pad 180B has inwardly tapered sidewalls extending from the top surface thereof to the bottom surface thereof.

As shown in the cross-sectional view 14000 of FIG. 14, a first ILD 110 is formed over the first buried bonding structure 180, multiple first conductive bonding contacts 180C are formed within the first ILD 110 and coupled to the multiple first conductive bonding pads 180B, a first RDL 121 is formed over the first buried bonding structure 180 and coupled to one or more of the multiple first conductive bonding pads 180B, multiple layers of first memory cells 130 are formed over and coupled to the first RDL 121, and a second RDL 122 is formed over and coupled to the multiple layers of first memory cells 130 by employing for example photolithography, etching, deposition, and CMP processes.

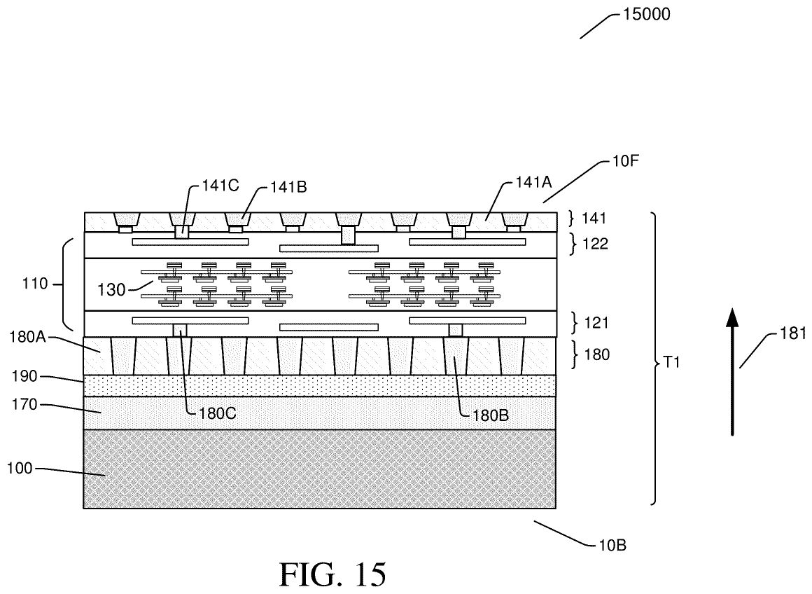

As shown in the cross-sectional view 15000 of FIG. 15, multiple first conductive bonding contacts 180C are formed within the first ILD 110 and coupled to the multiple first conductive bonding pads 180B of the first buried bonding structure 180, and a first front bonding structure 141 is formed over and coupled to the second ILD 122 by one or more of the multiple first conductive bonding contacts 180C, by employing for example photolithography, etching, deposition, and CMP processes. In some embodiments, the first front bonding structure 141 includes a first front dielectric bonding layer 141A over the first ILD 110 and multiple first front conductive bonding pads 141B partially embedded within the first front dielectric bonding layer 141A and exposed along the frontside surface 10F of the first memory wafer T1. In some embodiments, similar to the multiple first conductive bonding pads 180B, the multiple first front conductive bonding pads 141B exhibit funnel-shaped profiles, each first front conductive bonding pad 141B has inwardly tapered sidewalls extending from the top surface thereof to the bottom surface thereof.

In this way, an intermediate memory wafer including a buried bonding structure over a sacrificial dielectric and a semiconductor substrate (both of which will be removed in the future to expose the buried bonding structure) and a front bonding structure is formed. The intermediate memory wafer can be bonded to a base logic wafer, or bonded to another memory wafer by employing the buried bonding structure and/or the front bonding structure with enhanced design flexibility and simplified process flow.

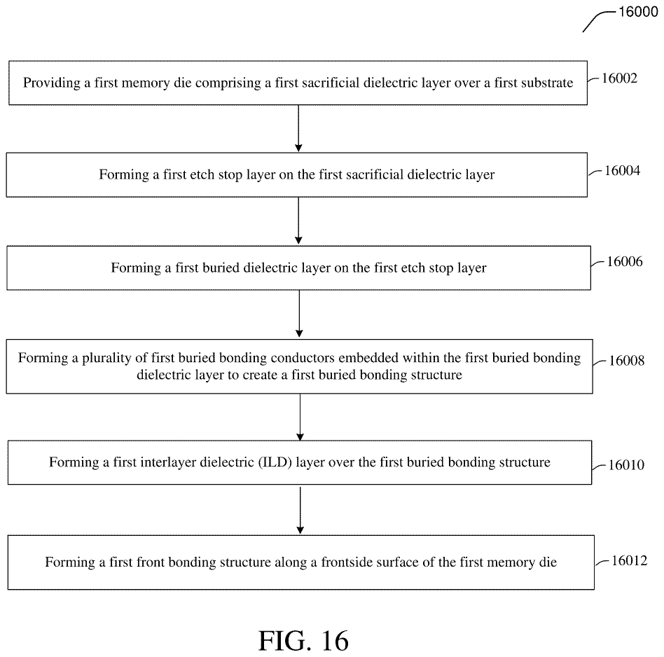

FIG. 16 illustrates a flow diagram of a method 16000 of manufacturing an intermediate memory wafer (e.g., T1 in FIG. 15) including a buried bonding structure over a sacrificial dielectric that is arranged over a semiconductor substrate according to some embodiments. It should be noted that the method 16000 is merely an example, and is not intended to limit the present disclosure. Accordingly, it is understood that the order of operations of the method 16000 of FIG. 16 can be changed, additional operations can be provided before, during, and after the method 16000 of FIG. 16, and other operations may be described briefly herein.

Referring to FIGS. 10 and 16, the method 16000 starts with operation 16002 of providing a first memory wafer T1 including a first sacrificial dielectric layer 170 over a first substrate 100. In some embodiments, the first substrate 100 includes a semiconductor material selected from silicon, SiC, GaAs, GaN, Ge, Al₂O₃, InP, or synthetic. In some embodiments, the first sacrificial dielectric layer 170 includes silicon oxide, such as SiO₂.

Referring to FIGS. 10 and 16, the method 16000 also includes operation 16004 of providing forming a first etch stop layer 190 on the first sacrificial dielectric layer 170 by employing a deposition process ((such as CVD and PVD). In some embodiments, the first etch stop layer 190 includes a material selected from Silicon Nitride (Si₃N₄), Titanium Nitride (TiN), or Aluminum Oxide (Al₂O₃).

Referring to FIGS. 10 and 16, the method 16000 proceeds to operation 16006 of providing forming a first buried dielectric bonding layer 180A on the first etch stop layer by employing a deposition process ((such as CVD and PVD). In some embodiments, the first buried dielectric bonding layer 180A includes a dielectric material, such as SiO_{2.}

Referring to FIGS. 11-13 and 16, the method 16000 proceeds to operation 16008 of providing forming a plurality of first conductive bonding pads 180B (in FIG. 13) embedded within the first buried bonding dielectric layer 180A to create a first buried bonding structure 180 (in FIG. 13). As shown in FIGS. 11-13, multiple openings 1102 in FIG. 11 are formed through the first buried dielectric bonding layer 180A and stop at the top surface of the etch stop layer 190 by employing for example photolithography and etching processes, a conductive material 180B′ in FIG. 12 is filled into the multiple openings 1102 (in FIG. 11) by employing for example a deposition (such as CVD and PVD) process, and excessive conductive material 180B′ (in FIG. 12) beyond the plurality of openings 1102 (in FIG. 11) is removed in FIG. 13 by employing for example a CMP process. As such, a first buried bonding structure 180 including the first buried dielectric bonding layer 180A and the multiple first conductive bonding pads 180B is formed in the first memory wafer T1.

Referring to FIGS. 14 and 16, the method 16000 proceeds to operation 16010 of providing forming a first interlayer dielectric (ILD) layer 110 over the first buried bonding structure 180. In some embodiments, as shown in FIG. 14, multiple first conductive bonding contacts 180C are formed within the first ILD 110 and coupled to the multiple first conductive bonding pads 180B, a first RDL 121 is formed over the first buried bonding structure 180 and coupled to one or more of the multiple first conductive bonding pads 180B, multiple layers of first memory cells 130 are formed over and coupled to the first RDL 121, and a second RDL 122 is formed over and coupled to the multiple layers of first memory cells 130 by employing for example photolithography, etching, deposition, and CMP processes.

Referring to FIGS. 15 and 16, the method 16000 proceeds to operation 16012 of providing forming a first front bonding structure 141 along a frontside surface 10F of the first memory wafer T1. In some embodiments, the first front bonding structure 141 includes a first front dielectric bonding layer 141A over the first ILD 110, multiple first front conductive bonding pads 141B partially embedded within the first front dielectric bonding layer 141A and exposed along the frontside surface 10F of the first memory wafer T1, and one or more first front conductive bonding contacts 141C to couple one or more of the multiple first front conductive bonding pads 141B to the adjacent second RDL 122.

In some embodiments, as aforementioned with respect to FIG. 5, the first memory wafer T1 can be flipped and bonded to a logic wafer T0 by using the first front bonding structure 141 of the first memory wafer T1 and the front bonding structure L141 of the base logic wafer T0, and the first semiconductor substrate 100 and the first sacrificial dielectric layer 170 can be removed by a laser lift-off process.

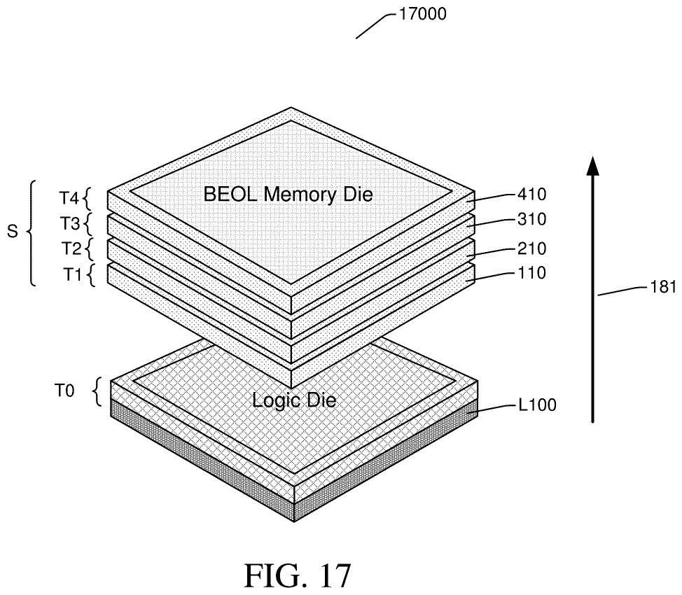

FIG. 17 illustrates a schematic view of a 3D integrated circuit (IC) package 17000 including a logic wafer T0 and a stack S of memory wafers (e.g., T1, T2, T3 and T4) bonded to the logic wafer T0 according to other embodiments of the present disclosure. The IC package 17000 as shown in FIG. 17 is similar to the IC package 1000 as shown in FIG. 1A with some exceptions. Similarly, the IC package 17000 includes a logic wafer T0 having a substrate L100, and a stack S of memory wafers (e.g., T1, T2, T3, and T4) bonded to the logic wafer T0. Similarly, none of the memory wafers (e.g., T1, T2, T3 and T4) in the stack S of the IC package 17000 includes a logic device therein. Similarly, none of the memory wafers (e.g., T1, T2, T3 and T4) in the stack S of the IC package 17000 includes a substrate therein, while in other embodiments, only a topmost memory wafer (e.g., T4) of the memory wafers (e.g., T1, T2, T3 and T4) in the stack S of the IC package 17000 includes a substrate (not shown). Differently, the base logic wafer T0 and the stack S of memory wafers (e.g., T1, T2, T3 and T4) in the IC package 17000 all stand in the upright orientation 181.

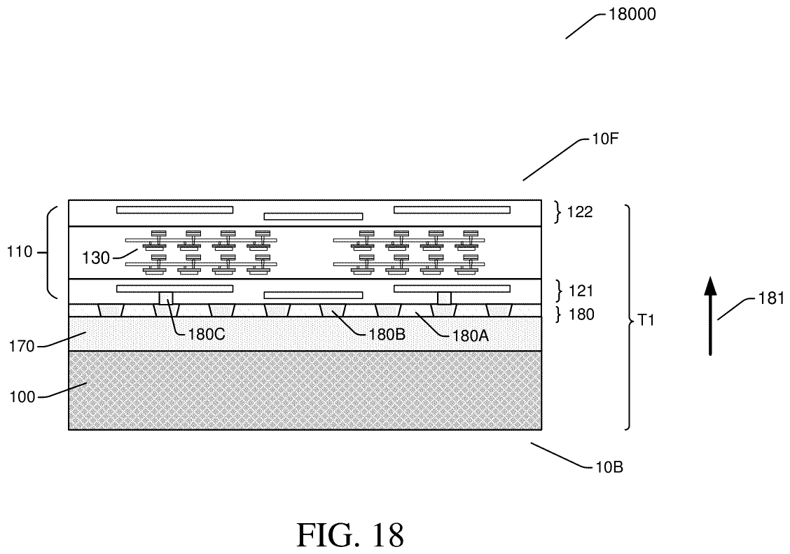

FIGS. 18-26 are a series of cross-sectional views of intermediate semiconductor structures that illustrate some exemplary steps of a method for manufacturing a 3D IC package including a stack of memory wafers bonded to a logic wafer in FIG. 17 according to some embodiments. Although FIGS. 18-26 are described in relation to a method, it will be appreciated that the structures disclosed in FIGS. 18-26 are not limited to such a method, but instead may stand alone as structures independent of the method.

As shown in the cross-sectional view 18000 of FIG. 18, a first memory wafer T1 is provided and stands in an original upright orientation 181. In some embodiments, the first memory wafer T1 includes a first substrate 100, a first sacrificial dielectric layer 170 over the first substrate 100, a first buried bonding structure 180 over the first sacrificial dielectric layer 170, a first interlayer dielectric (ILD) layer 110 over the first buried bonding structure 180, a first RDL 121 within the first ILD layer 110 and over the first buried bonding structure 180, and a second RDL 122 within the first ILD layer 110 and over the first RLD 121. In some embodiments, the first buried bonding structure 180 includes a first buried dielectric bonding layer 180A along a top surface of the first sacrificial dielectric layer 170, multiple first buried conductive bonding pads 180B embedded within first buried dielectric bonding layer 180A, and multiple first conductive bonding contacts 180C embedded within the first ILD 110 to couple the multiple first conductive bonding pads 180B to the adjacent first RDL 121. In some embodiments, the first memory wafer T1 also includes multiple layers of first memory cells 130 that are disposed within the first ILD 110 and vertically between the first RDL 121 and the second RDL 122.

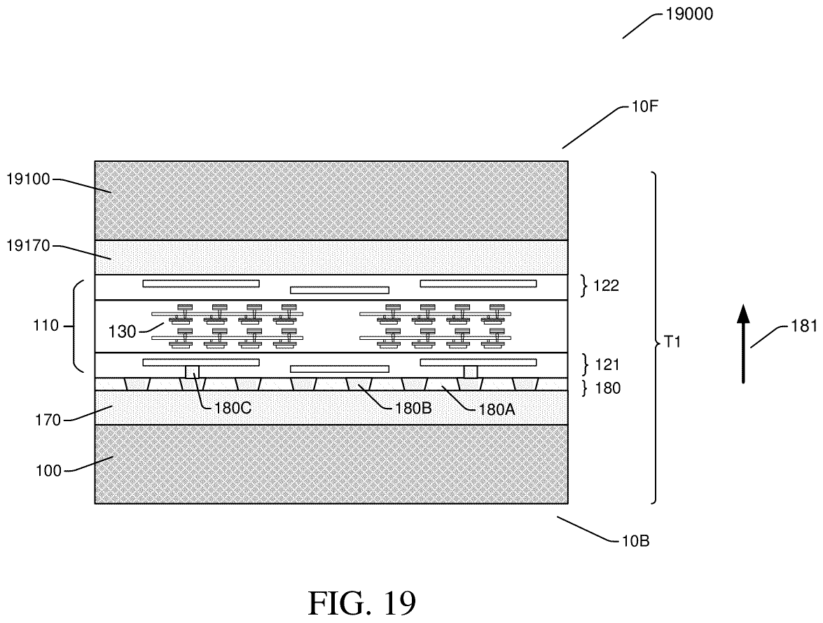

As shown in the cross-sectional view 19000 of FIG. 19, a second sacrificial dielectric layer 19170 is formed over the second RDL and then a first carrier substrate 19100 is formed over the second sacrificial dielectric layer 19170 by employing for example deposition (such as CVD and/or PVD) processes.

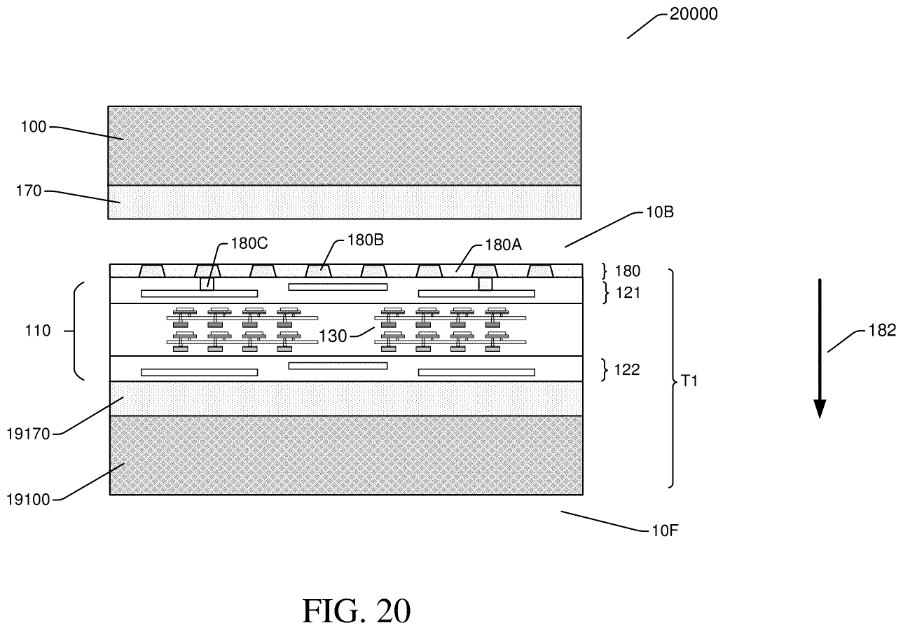

As shown in the cross-sectional view 20000 of FIG. 20, a first flipping is performed to the first memory wafer T1, and then the first substrate 100 and the first sacrificial dielectric layer 170 are removed by employing a laser lift-off process to expose the first buried bonding structure 180. Thus, the first memory wafer T1 with reduced height or thickness stands in a flipped orientation 182.

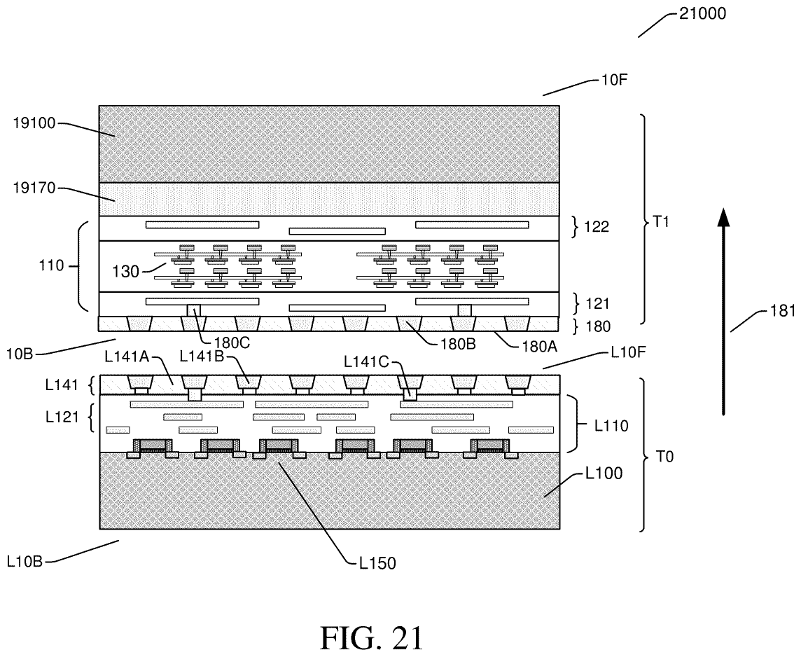

As shown in the cross-sectional view 21000 of FIG. 21, a second flipping is performed to the first memory wafer T1, and a base logic wafer T0 standing in the upright orientation 181 is provided. As such, both the first memory wafer T1 and the base logic wafer T0 stand in the upright orientation 181. In some embodiments, the base logic wafer T0 includes a substrate L100, one or more logic devices L150 in a FEOL arranged along a frontside surface L10F of the substrate L100, an ILD L110 over substrate L100, a RDL L121 within the ILD L110 and over the logic devices L150, and a front bonding structure L141 along a frontside surface L10F of the base logic wafer T0. In some embodiments, the front bonding structure L141 of the base logic wafer T0 includes a dielectric bonding layer L141A, multiple conductive bonding pads L141B along the frontside surface L10F of the logic wafer T0, and multiple conductive bonding contacts L141C to couple the multiple conductive bonding pads L141B to the RDL L121.

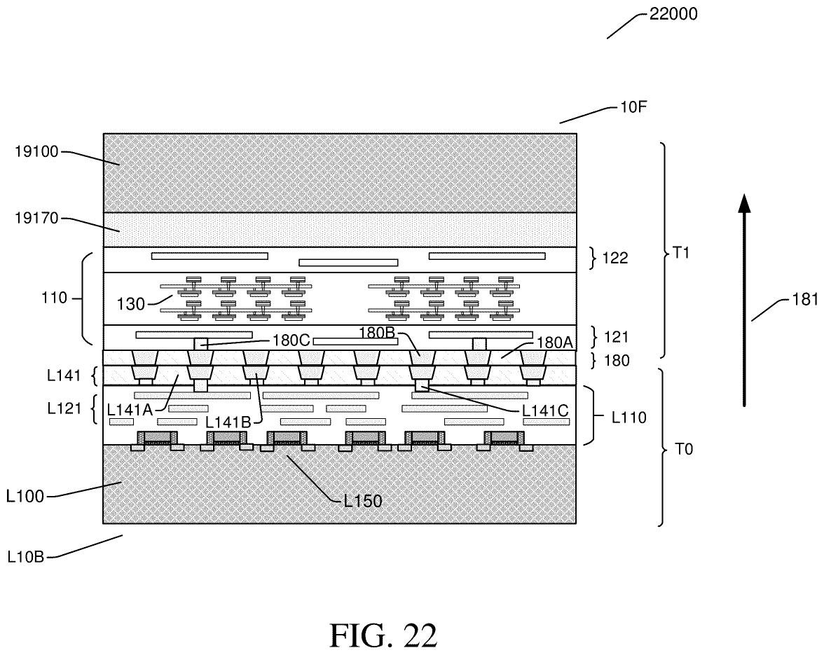

As shown in the cross-sectional view 22000 of FIG. 22, the first memory wafer T1 is bonded to the base logic wafer T0 by bonding the first buried bonding structure 180 of the first memory wafer T1 and the front bonding structure L141 of the base logic wafer T0. In some embodiments, the first buried dielectric bonding layer 180A of the first buried bonding structure 180 of the first memory wafer T1 is bonded to the dielectric bonding layer L141A of the front bonding structure L141 of the base logic wafer T0, and the multiple first conductive bonding pads 180B of the first buried bonding structure 180 of the first memory wafer T1 is bonded to the multiple conductive bonding pads L141B of the front bonding structure L141 of the base logic wafer T0.

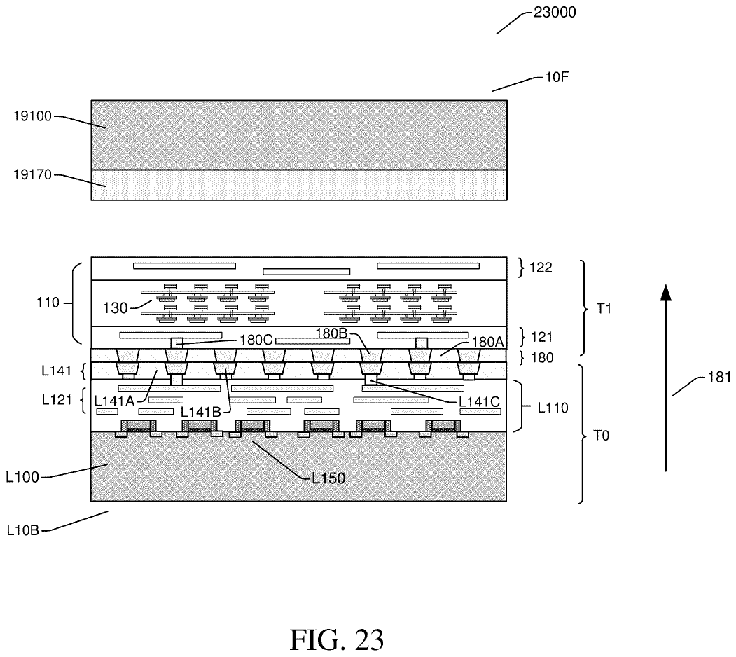

As shown in the cross-sectional view 23000 of FIG. 23, the first carrier substrate 19100 and the second sacrificial dielectric layer 19170 are removed from the first memory wafer T1 to expose the second RDL 122 by employing for example a laser lift-off process as aforementioned.

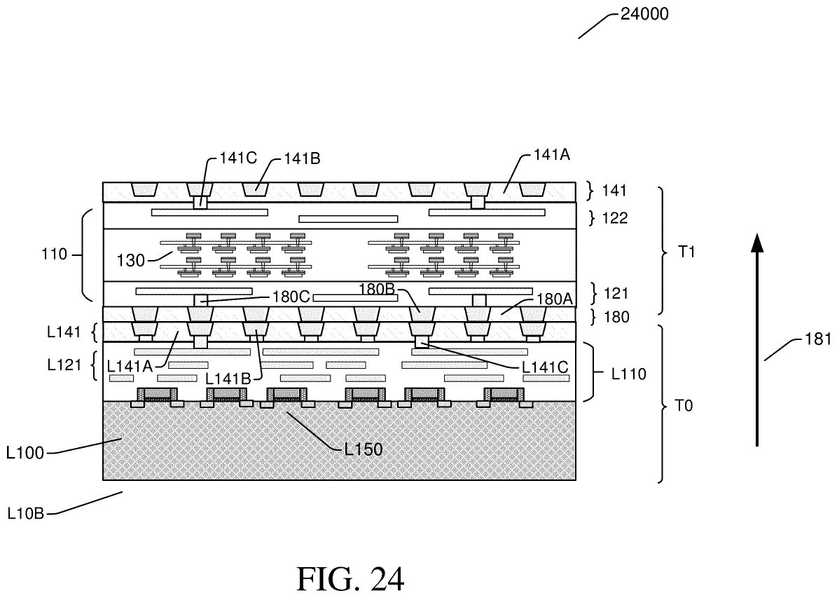

As shown in the cross-sectional view 24000 of FIG. 24, a first front bonding structure 141 is formed over the second RDL 122 by employing for example photolithography, etching, deposition, and CMP processes. In some embodiments, the first front bonding structure 141 includes a first front dielectric bonding layer 141A over the first ILD 110, multiple first front conductive bonding pads 141B partially embedded within the first front dielectric bonding layer 141A and exposed along the frontside surface 10F of the first memory wafer T1, and one or more first front conductive bonding contacts 141C to couple one or more of the multiple first front conductive bonding pads 141B to the adjacent second RDL 122.

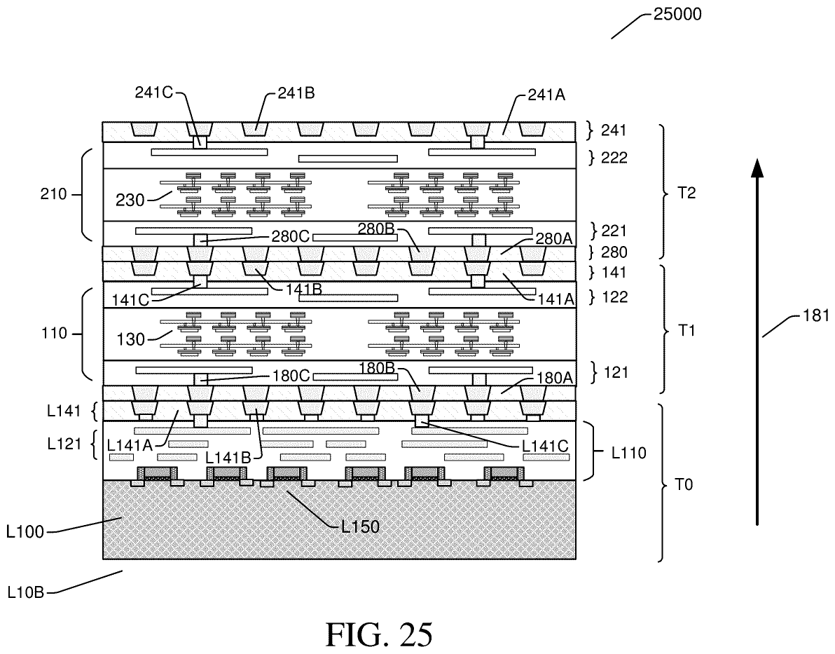

As shown in the cross-sectional view 25000 of FIG. 25, a second memory wafer T2 is provided, processed, and bonded to the first memory wafer T1. Similar to the first memory wafer T1 as shown in FIG. 6, the second memory wafer T2 includes a second substrate 200, a second sacrificial dielectric layer 270 over the second substrate 200, a second buried bonding structure 280 over the second sacrificial dielectric layer 270, a second interlayer dielectric (ILD) layer 210 over the second buried bonding structure 280, a third RDL 221 within the second ILD layer 210 and over the second buried bonding structure 280, and a fourth RDL 222 within the second ILD layer 210 and over the adjacent third RLD 221. In some embodiments, the second buried bonding structure 280 includes a second buried dielectric bonding layer 280A along a top surface of the second sacrificial dielectric layer 270, multiple second conductive bonding pads 280B embedded within second buried dielectric bonding layer 280A, and multiple second conductive bonding contacts 280C embedded within the second ILD 210 to couple the multiple second conductive bonding pads 280B to the adjacent third RDL 221. In some embodiments, the second memory wafer T2 also includes multiple layers of second memory cells 230 that are disposed within the second ILD 210 and vertically between the third RDL 221 and the fourth RDL 122.

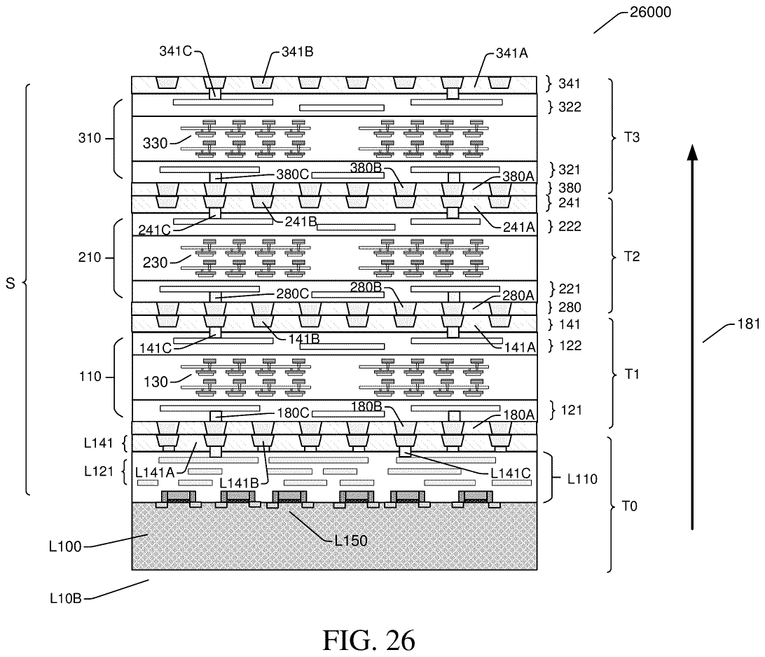

As shown in the cross-sectional view 26000 of FIG. 26, similarly, a third memory wafer T3 is provided, processed, and bonded to the second memory wafer T2. In this way, more memory wafers (such as T4-T10) can be provided, processed, and bonded to the stack S of the memory wafers (such as T1, T2, and T3).

As such, a 3D IC package including a stack S of memory wafers (e.g., T1-T3) and the base logic wafer T0 bonded together and all standing in the upright orientation 181 is manufactured, in which each (e.g., T1) of the memory wafers includes a buried bonding structure (e.g., 180) that will be exposed after removing a substrate (e.g., a first substrate 100) and a sacrificial dielectric layer (e.g., a first sacrificial dielectric layer 170) thereover by a laser lift-off process, thereby advantageously providing enhanced design flexibility, simplifying the process flow of forming the bonding structures of the memory wafers, reducing defect source and wafer broken risk by getting rid of a wafer BS silicon grinding process that may need extra wafer edge engineering process like edge sealing, edge trim, and dry/wet clean, and obtaining well-controlled surface roughness and thermal budget to improve product yield and device performance.

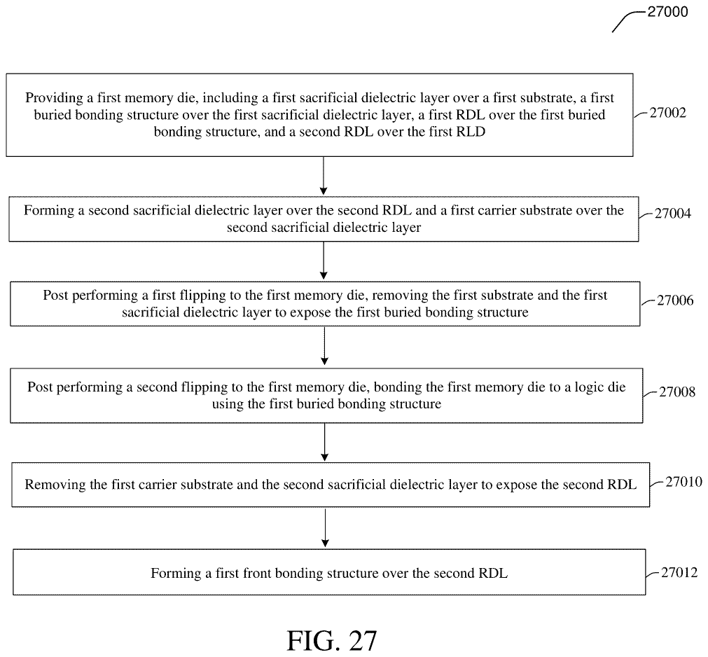

FIG. 27 illustrates a flow diagram of a method 27000 of manufacturing a 3D IC package including a stack of memory wafers bonded to a logic wafer in FIG. 17 according to some embodiments. _ It should be noted that the method 27000 is merely an example, and is not intended to limit the present disclosure. Accordingly, it is understood that the order of operations of the method 27000 of FIG. 27 can be changed, additional operations can be provided before, during, and after the method 27000 of FIG. 27, and other operations may be described briefly herein.

Referring to FIGS. 18 and 27, the method 27000 starts with operation 27002 of providing a first memory wafer T1 and stands in an original upright orientation 181. In some embodiments, the first memory wafer T1 includes a first substrate 100, a first sacrificial dielectric layer 170 over the first substrate 100, a first buried bonding structure 180 over the first sacrificial dielectric layer 170, a first interlayer dielectric (ILD) layer 110 over the first buried bonding structure 180, a first RDL 121 within the first ILD layer 110 and over the first buried bonding structure 180, and a second RDL 122 within the first ILD layer 110 and over the first RLD 121.

Referring to FIGS. 19 and 27, the method 27000 also includes operation 27004 of forming a second sacrificial dielectric layer 19170 over the second RDL 122 and a first carrier substrate 19100 over the second sacrificial dielectric layer 19170 by employing for example deposition (such as CVD and/or PVD) processes.

Referring to FIGS. 20 and 27, the method 27000 proceeds to operation 27006 of post performing a first flipping to the first memory wafer T1 to a flipped orientation 182, removing the first substrate 100 and the first sacrificial dielectric layer 170 of the first memory wafer T1 to expose the first buried bonding structure 180 by employing for example a laser lift-off process.

Referring to FIGS. 21-22 and 27, the method 27000 proceeds to operation 27008 of post performing a second flipping to the first memory wafer T1 to an upright orientation 181, bonding the first memory wafer T1 to a base logic wafer T0 using the first buried bonding structure 180 of the first memory wafer T1. In some embodiments, the first buried dielectric bonding layer 180A of the first buried bonding structure 180 of the first memory wafer T1 is bonded to the dielectric bonding layer L141A of the front bonding structure L141 of the base logic wafer T0, and the multiple first conductive bonding pads 180B of the first buried bonding structure 180 of the first memory wafer T1 is bonded to the multiple conductive bonding pads L141B of the front bonding structure L141 of the base logic wafer T0.

Referring to FIGS. 23 and 27, the method 27000 proceeds to operation 27010 of removing the first carrier substrate 19100 and the second sacrificial dielectric layer 19170 to expose the second RDL 122 of the first memory wafer T1 by employing for example another laser lift-off process.

Referring to FIGS. 24 and 27, the method 27000 proceeds to operation 27012 of forming a first front bonding structure 141 over the second RDL 122 of the first memory wafer T1 by employing for example photolithography, etching, deposition, and CMP processes. In some embodiments, the first front bonding structure 141 includes a first front dielectric bonding layer 141A over the first ILD 110, multiple first front conductive bonding pads 141B partially embedded within the first front dielectric bonding layer 141A and exposed along the frontside surface 10F of the first memory wafer T1, and one or more first front conductive bonding contacts 141C to couple one or more of the multiple first front conductive bonding pads 141B to the adjacent second RDL 122.

Referring to FIG. 25, a second memory wafer T2 is provided, processed, and bonded to the first memory wafer T1. Referring to FIG. 26, similarly, a third memory wafer T3 is provided, processed, and bonded to the second memory wafer T2. In this way, more memory wafers (such as T4-T10) can be provided, processed, and bonded to the stack S of the memory wafers (such as T1, T2, and T3). As such, a 3D IC package including a stack S of memory wafers (e.g., T1-T3) and the base logic wafer T0 bonded together and all standing in the upright orientation 181 is manufactured.

FIGS. 28A and 28B respectively are a schematic view and a cross-sectional view illustrating a first memory wafer T1 and a base logic wafer T0 face-to-face bonded to each other by a bonding structure included in a portion 2841 according to some embodiments. In some embodiments, the bonding structure is a combination of the first front bonding structure 141 of the first memory wafer T1 and the front bonding structure L141 of the base logic wafer T0 as shown in FIG. 4.

FIGS. 29A and 29B respectively are a schematic view and a cross-sectional view illustrating the first memory wafer T1 and the base logic wafer T0 bonded to each other with a substrate (e.g., 100 in FIG. 5) and a sacrificial dielectric layer (e.g., 170 in FIG. 5) of the first memory wafer T1 removed therefrom according to some embodiments.

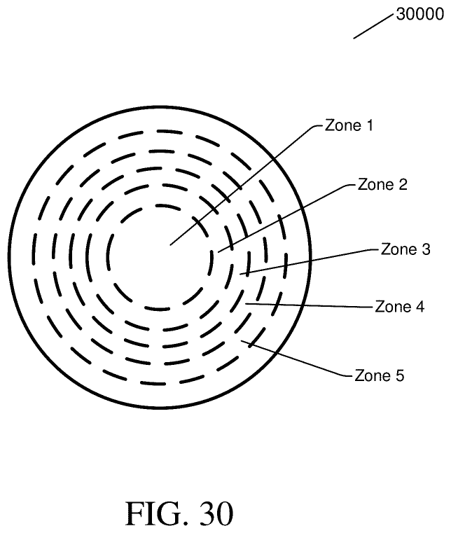

FIG. 30 is a top view of a wafer (e.g., a first memory wafer T1) illustrating laser irradiated onto various zones (such as zone 1, zone 2, zone 3, zone 4, and zone 5) on a surface of the wafer according to some embodiments. In some embodiments, a laser is irradiated onto the interface between a silicon (Si) substrate and an oxide layer thereover. The irradiated silicon undergoes a transformation into silicon oxide. Due to the mismatch in the coefficient of thermal expansion (CTE) between the irradiated and non-irradiated regions, a laser lift-off process can be initiated at the silicon/oxide interface. In some embodiments, the laser can be adjusted with respect to frequency (e.g., in a range of 1-500 kHz), pulse energy (e.g., in a range of 1-500 uJ), pulse pitch (e.g., in a range of 1-100 um), and zone setting (e.g., in a range of 1-10).

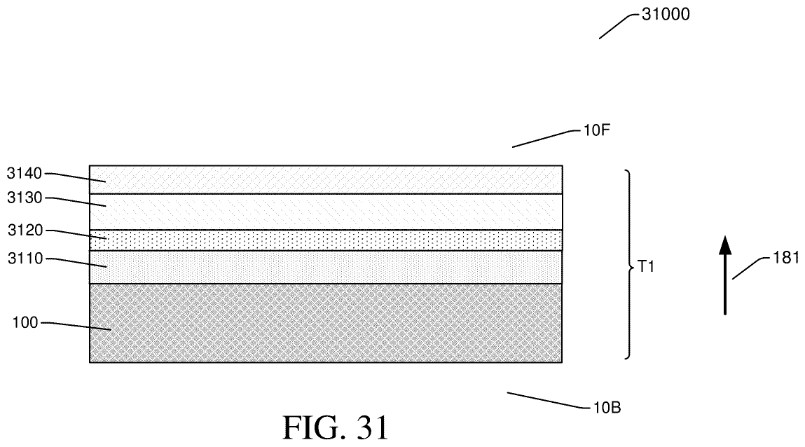

FIGS. 31-39 are a series of cross-sectional views of intermediate semiconductor structures that illustrate some exemplary steps of a method for manufacturing a 3D IC package including a stack of memory wafers bonded to a logic wafer according to still other embodiments. Although FIGS. 31-39 are described in relation to a method, it will be appreciated that the structures disclosed in FIGS. 31-39 are not limited to such a method, but instead may stand alone as structures independent of the method.

As shown in the cross-sectional view 31000 of FIG. 31, a first memory wafer Tl is provided and stands in an original upright orientation 181. In some embodiments, the first memory wafer T1 includes a first substrate 100, a buffer layer 3110 disposed on the first substrate 100, a thermal dissipation layer 3120 disposed on the buffer layer 3110, a delamination layer 3130 on the thermal dissipation layer 3120, and a reflection layer 3140 on the delamination layer 3130. The first memory wafer T1 includes a frontside surface 10F and a backside surface 10B.

In some embodiments, the first substrate 100 includes a semiconductor material selected from silicon, SiC, GaAs, GaN, Ge, Al₂O₃, InP, or synthetic. In some embodiments, the buffer layer 3110 includes an oxide material, Tetraethyl Orthosilicate (TEOS), Undoped Silicate Glass (USG), and Low-k Dielectric, or the like. In some embodiments, the thermal dissipation layer 3120 includes SiN, SiON, SiCN, or other dielectric material. In some embodiments, the delamination layer 3130 includes an oxide material, Tetraethyl Orthosilicate (TEOS), Undoped Silicate Glass (USG), and Low-k Dielectric, an oxide layer, or the like. In some embodiments, the reflection layer 3140 includes N, Ti, W, Ru, Cu, or other metal materials.

In some embodiments, the first sacrificial dielectric layer 170 includes silicon oxide, such as SiO₂. In some embodiments, the first buried dielectric bonding layer 180A includes a dielectric material, such as SiO₂. In some embodiments, the one or more first conductive bonding pads 180B includes a conductive material, such as copper (Cu), copper alloy (e.g., Cu—Mn), Nickel (Ni), Gold (Au). In some embodiments, the etch stop layer 190 includes a material selected from Silicon Nitride (Si₃N₄), Titanium Nitride (TiN), or Aluminum Oxide (Al₂O₃).

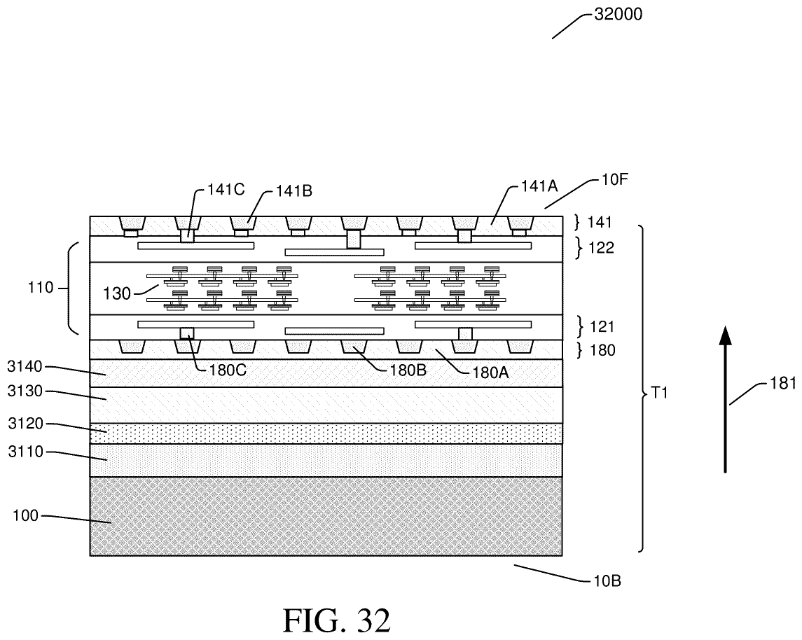

As shown in the cross-sectional view 32000 of FIG. 32, a first buried bonding structure 180 is formed over the reflection layer 3140 of the first memory wafer T1, a first ILD 110 is formed over the first buried bonding structure 180, a first pair of RDLs 121 and 122 is formed within the first ILD 110, multiple layers of first memory cells 130 are formed vertically between the first pair of RDLs 121 and 122, and a first front bonding structure 141 is formed along the frontside surface 10F of the first memory wafer T1.

In some embodiments, the first buried bonding structure 180 of the first memory wafer T1 includes a first buried dielectric bonding layer 180A (e.g., a dielectric, TEOS, USG, or the like) along a top surface of the reflection layer 3140, one or more first buried conductive bonding pads 180B (e.g., Cu, Cu alloy, Ni, Au, or the like) embedded within first buried dielectric bonding layer 180A, and one or more first conductive bonding contacts 180C (e.g., Cu, Ni, or the like) embedded within the first ILD 110 to couple the one or more first conductive bonding pads 180B to the adjacent first RDL 121. In some embodiments, the first front bonding structure 141 of the first memory wafer T1 includes a first front dielectric bonding layer 141A, one or more first front conductive bonding pads 141B along the frontside surface 10F of the first memory wafer T1, and one or more first front conductive bonding contacts 141C to couple the one or more first front conductive bonding pads 141B to the adjacent second RDL 122.

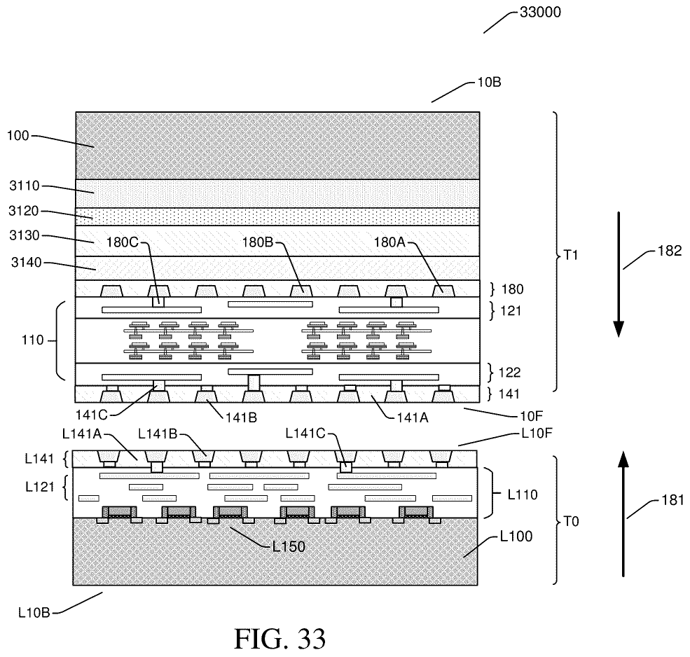

As shown in the cross-sectional view 33000 of FIG. 33, the first memory wafer Tl is flipped (thus standing in a flipped orientation 182), and a base logic wafer T0 is provided (standing in an upright orientation 181). In some embodiments, the base logic wafer T0 includes a substrate L100, one or more logic devices L150 in the FEOL arranged along a frontside surface L10F of the substrate L100, an ILD L110 over substrate L100, a redistribution layer (RDL) L121 within the ILD L110 and over the logic devices L150, and a front bonding structure L141 along a frontside surface L10F of the base logic wafer T0. In some embodiments, the front bonding structure L141 of the base logic wafer T0 includes a dielectric bonding layer L141A, multiple conductive bonding pads L141B along the frontside surface L10F of the logic wafer T0, and multiple conductive bonding contacts L141C to couple the multiple conductive bonding pads L141B to the RDL L121.

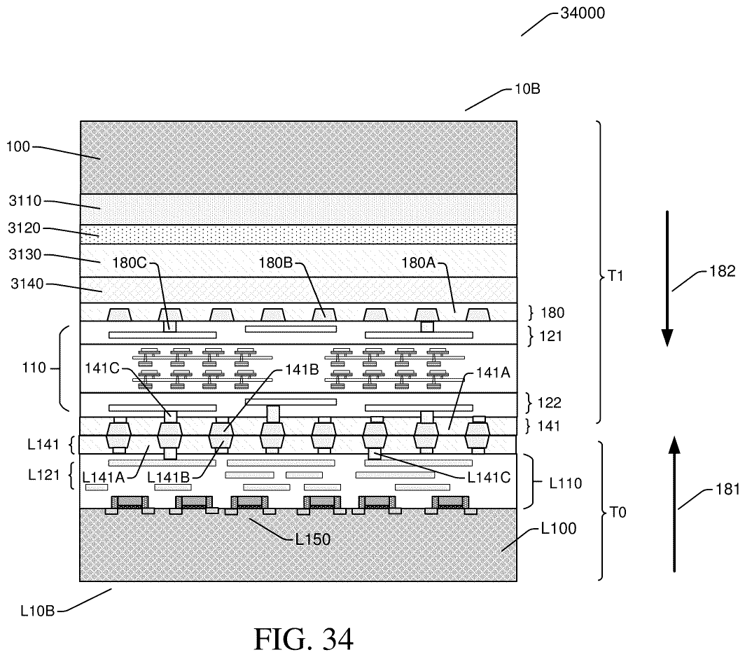

As shown in the cross-sectional view 34000 of FIG. 34, the flipped first memory wafer T1 is face-to-face bonded to the base logic wafer T0. In some embodiments, the first front dielectric bonding layer 141A of the first front bonding structure 141 of the first memory wafer T1 is bonded to the dielectric bonding layer L141A of the front bonding structure L141 of the base logic wafer T0, and the multiple first front conductive bonding pads 141B of the first front bonding structure 141 of the first memory wafer T1 are bonded to the multiple conductive bonding pads L141B of the front bonding structure L141 of the base logic wafer T0. Thus, the first memory wafer T1 is face-to-face bonded to the base logic wafer T0 by the first front bonding structure 141 of the first memory wafer T1 and the front bonding structure L141 of the base logic wafer T0.

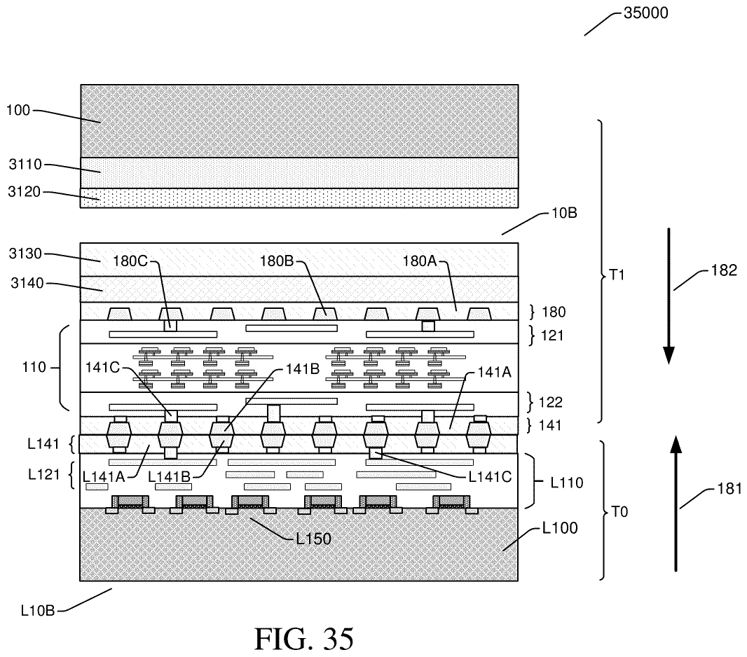

As shown in the cross-sectional view 35000 of FIG. 35, the first substrate 100, the buffer layer 3110, and the thermal dissipation layer 3120 are removed by a laser lift-off process to expose the reflection layer 3140 from the backside surface 10B of the first memory wafer T1.

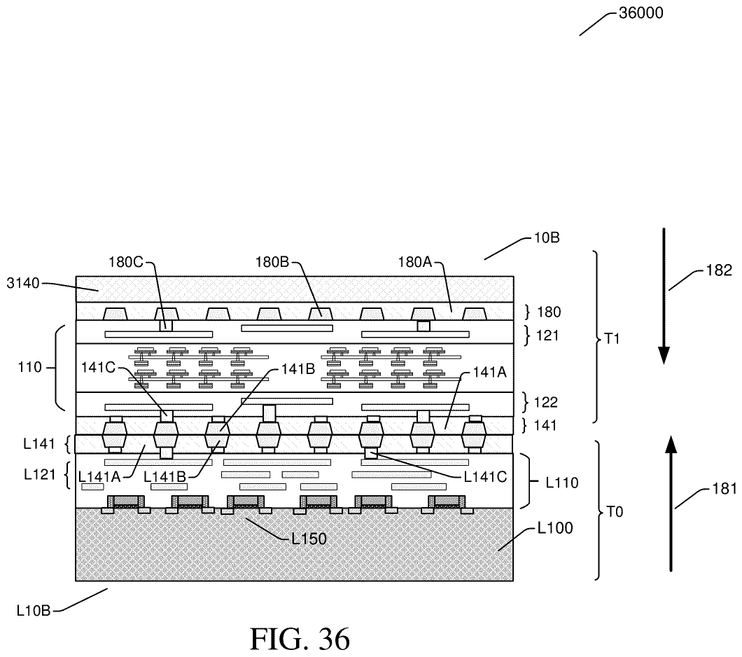

As shown in the cross-sectional view 36000 of FIG. 36, the delamination layer 3130 in FIG. 35 is removed by a wet etching process, a dry etching process, or a CMP process to expose the reflection layer 3140.

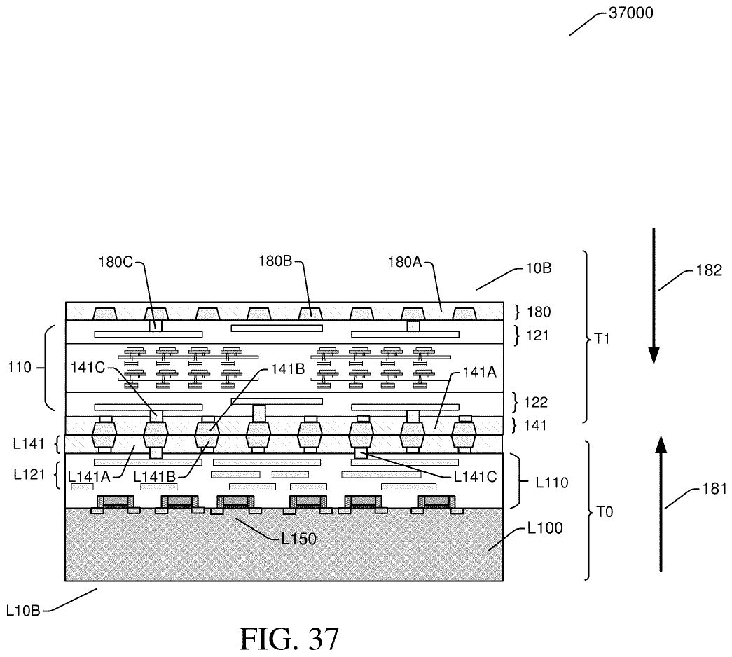

As shown in the cross-sectional view 37000 of FIG. 37, the reflection layer 3140 in FIG. 36 is removed by a wet etching process, a dry etching process, or a CMP process to expose the first buried bonding structure 180 from the backside surface 10B of the first memory wafer T1.

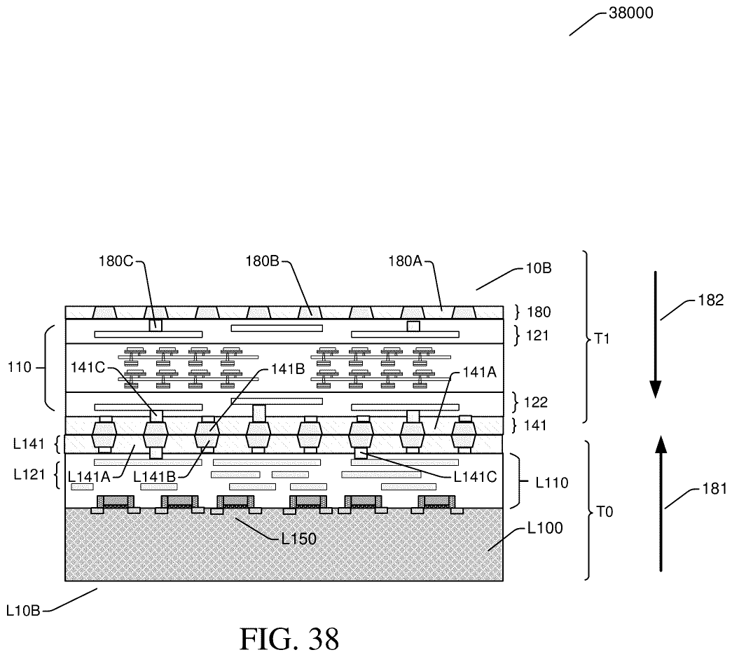

As shown in the cross-sectional view 38000 of FIG. 38, a CMP process is performed to the first buried bonding structure 180 to polarize the first buried bonding structure 180 and remove a portion of the first buried bonding structure 180 to expose the multiple first buried conductive bonding pads 180B from the backside surface 10B of the first memory wafer T1.

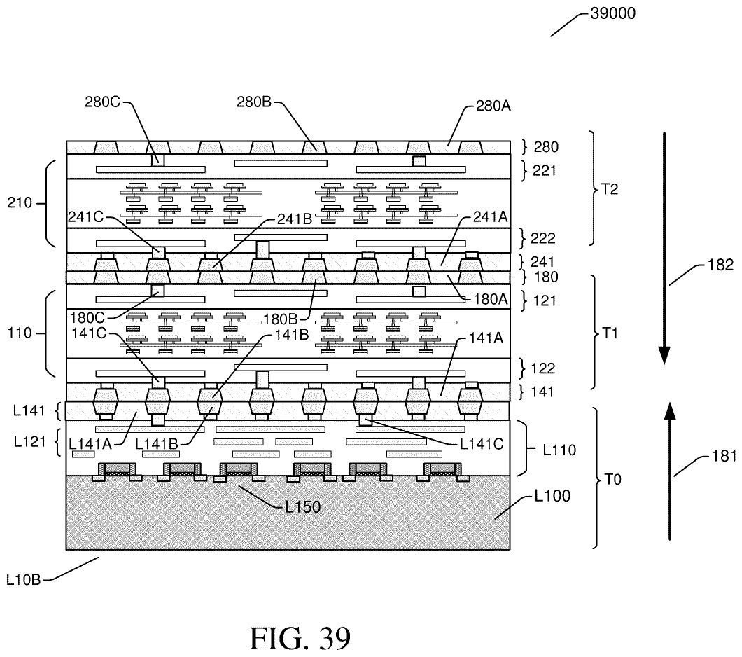

As shown in the cross-sectional view 39000 of FIG. 39, a second memory wafer T2 similar to the first memory wafer T1 is provided, flipped, and processed. The second memory wafer T2 includes a second front bonding structure 241 and a second buried bonding structure 280. The flipped second memory wafer T2 is bonded to the first memory wafer T1 by using second front bonding structure 241 and the first buried bonding structure 180. This process can be repeated so that more memory wafers (such as T1, T2, T3, T4, T5 . . . ) and the logic wafer T0 can be bonded together, thereby forming a wafer-to-wafer integrated chip.

After the wafer-to-wafer integrated chip is formed, the bonded wafer stack may be subjected to a thinning process, such as mechanical grinding, chemical mechanical polishing (CMP), or plasma etching, to reduce a thickness of one of the bonded wafers (not shown in the figures). A protective layer or dicing tape may then be applied to protect circuit regions during singulation (not shown in the figures). The bonded wafer stack may thereafter be diced into a plurality of individual dies by a singulation process, such as blade dicing, laser dicing, stealth dicing, or plasma dicing (not shown in the figures). Following singulation, the plurality of individual dies may be picked up from the dicing tape, optionally cleaned, and subsequently subjected to electrical testing and packaging (not shown in the figures), thereby creating individual die packages.

Accordingly, in some embodiments, a stack of memory wafers is provided. The stack includes a first memory wafer including a first pair of redistribution layers (RDLs) within a first interlayer dielectric (ILD) disposed over a first substrate, multiple layers of first memory cells between the first pair of RDLs, and a first bonding structure along a frontside surface of the first memory wafer. The second memory wafer, absenting a substrate, includes a second pair of RDLs within a second ILD of the second memory wafer, multiple layers of second memory cells between the second pair of RDLs, a second bonding structure along a frontside surface of the second memory wafer, facing and bonded to the first bonding structure, and a third bonding structure along a backside surface of the second memory wafer. In some embodiments, the bonding structure of the logic wafer comprises a bonding dielectric layer and a plurality of bonding conductors embedded within the bonding dielectric layer. In some embodiments, the first buried bonding structure of the first memory wafer comprises a first buried bonding dielectric layer and a plurality of first buried bonding conductors embedded within the first bonding dielectric layer. In some embodiments, coefficients of thermal expansion (CTEs) of the first substrate and the first sacrificial dielectric layer of the first memory wafer are different from coefficients of thermal expansion (CTEs) of the first buried bonding dielectric layer and the plurality of first buried bonding conductors of the first buried bonding structure of the first memory wafer. In some embodiments, the first substrate and the first sacrificial dielectric layer are removed from the first memory wafer by at least a laser lift-off process. In some embodiments, the method further comprises: forming a second memory wafer comprising a second sacrificial dielectric layer over a second substrate, a second buried bonding structure over the second sacrificial dielectric layer, and a second front bonding structure over the second buried bonding structure and along a frontside surface of the second memory wafer; flipping and bonding the second memory wafer to the first memory wafer, wherein the second front bonding structure of the second memory wafer is bonded to the first buried bonding structure of the first memory wafer; and removing the second substrate and the second sacrificial dielectric layer from the second memory wafer by another laser lift-off process to expose the second buried bonding structure from a backside surface of the second memory wafer. In some embodiments, the first memory wafer further comprises a first pair of redistribution layers (RDLs) within a first interlayer dielectric (ILD) over the first buried bonding structure, and one or more layers of first memory cells vertically between the first pair of RDLs. In some embodiments, one of the first memory cells is selected from a group consisting of a 1-Transistor 1-Capacitor (1T1C) Dynamic Random Access Memory (DRAM), a 2T (2-Transistor) DRAM, a 1-Transistor 1-Resistor (1T1R) Resistive Random Access Memory (RRAM), a 1T1C Ferroelectric Random Access Memory (FeRAM), and a 1-Transistor 1-Magnetic Tunnel Junction (1TIMTJ) Magnetoresistive Random Access Memory (MRAM).

In other embodiments, a method of manufacturing a stack of memory wafers is provided. The method includes providing a first memory wafer, wherein the first memory wafer comprises a first pair of redistribution layers (RDLs) within a first interlayer dielectric (ILD) over a first substrate, multiple layers of first memory cells vertically between the first pair of RDLs, and a first bonding structure along a frontside surface of the first memory wafer; providing a second memory wafer, wherein the second memory wafer includes a second pair of RDLs within a second ILD over a second substrate, multiple layers of second memory cells vertically between the second pair of RDLs, and a second bonding structure along a frontside surface of the second memory wafer; flipping and bonding the second memory wafer to the first memory wafer by bonding the second bonding structure to the first bonding structure; removing the second substrate from the second memory wafer; and forming a third bonding structure along a backside surface of the second memory wafer opposite to the frontside surface of the second memory wafer. In some embodiments, the method further comprises: flipping and bonding the first memory wafer to a logic wafer; and removing the first semiconductor substrate and the first sacrificial dielectric layer from the first memory wafer. In some embodiments, the first substrate and the first sacrificial dielectric layer are removed from the first memory wafer by a laser lift-off process. In some embodiments, the method further comprises: providing a second memory wafer comprising a second sacrificial dielectric layer over a second substrate; forming a second etch stop layer on the second sacrificial dielectric layer; forming a second buried dielectric layer on the second etch stop layer; forming a plurality of second buried bonding conductors embedded within the second buried bonding dielectric layer to create a second buried bonding structure; forming a second interlayer dielectric (ILD) layer over the second buried bonding structure; and forming a second front bonding structure along a frontside surface of the second memory wafer, wherein the second front bonding structure comprises a second front bonding dielectric layer over the second buried bonding dielectric layer and a plurality of second front bonding conductors embedded within the second front bonding dielectric layer. In some embodiments, the method further comprises: flipping and bonding the second memory wafer to the first memory wafer; and removing the second semiconductor substrate and the second sacrificial dielectric layer from the second memory wafer by a laser lift-off process. In some embodiments, the method further comprises: post forming the first ILD layer over the first buried bonding structure, forming a first redistribution layer (RDL) within the first ILD layer; forming one or more layers of first memory cells over the first RDL within the first ILD layer; and forming a second RDL within the first ILD layer over the one or more layers of first memory cells.

In yet other embodiments, a method of manufacturing a three-dimensional integrated circuit package is provided. The method includes providing a logic wafer, wherein the logic wafer includes a logic device therewithin, and a first bonding structure along a frontside surface thereof and coupled to the logic device; providing a first memory wafer, wherein the first memory wafer comprises a first pair of redistribution layers (RDLs) within a first interlayer dielectric (ILD) over a first substrate, multiple layers of first memory cells vertically between the first pair of RDLs, and a second bonding structure along a frontside surface of the first memory wafer; flipping and bonding the first memory wafer to the logic wafer by bonding the second bonding structure to the first bonding structure; removing the first substrate from the first memory wafer; and forming a third bonding structure along a backside surface of the first memory wafer opposite to the frontside surface of the first memory wafer. In some embodiments, the method further comprises forming a plurality of first memory cells formed vertically between the first RDL and the second RDL. In some embodiments, the first substrate and the first sacrificial dielectric layer are removed by a first laser lift-off process, and wherein the first carrier substrate and the second sacrificial dielectric layer are removed by a second laser lift-off process. In some embodiments, the first buried bonding structure of the first memory wafer is formed to comprise a first buried bonding dielectric layer and a plurality of first buried bonding conductors embedded within the first bonding dielectric layer. In some embodiments, the first front bonding structure is formed to comprise a first front bonding dielectric layer and a plurality of first front bonding conductors embedded within the first front bonding dielectric layer. In some embodiments, the method further comprises: providing a second memory wafer, the second memory wafer comprising a third sacrificial dielectric layer over a second substrate, a second buried bonding structure within a third interlayer dielectric (ILD) layer over the third sacrificial dielectric layer, a third RDL over the second buried bonding structure, and a fourth RDL over the third RLD; forming a fourth sacrificial dielectric layer over the fourth RDL and a second carrier substrate over the fourth sacrificial dielectric layer; post performing a first flipping to the second memory wafer, removing the second substrate and the third sacrificial dielectric layer to expose the second buried bonding structure; post performing a second flipping to the second memory wafer, bonding the second memory wafer to the first memory wafer using the second buried bonding structure of the second memory wafer and the first front bonding structure of the first memory wafer; removing the second carrier substrate and the fourth sacrificial dielectric layer to expose the fourth RDL; and forming a second front bonding structure over the fourth RDL.

It will be appreciated that while reference is made throughout this document to exemplary structures in discussing aspects of methodologies described herein that those methodologies are not to be limited by the corresponding structures presented. Rather, the methodologies (and structures) are to be considered independent of one another and able to stand alone and be practiced without regard to any of the particular aspects depicted in the Figs. Additionally, layers described herein, can be formed in any suitable manner, such as with spin on, sputtering, growth and/or deposition techniques, etc.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of manufacturing a three-dimensional integrated circuit package, comprising:
providing a logic wafer comprising a front bonding structure along a frontside surface of the logic wafer and coupled to a logic device within the logic wafer die, wherein the logic wafer comprises a logic die;
providing a first memory wafer comprising a first sacrificial dielectric layer over a first substrate, a first buried bonding structure over the first sacrificial dielectric layer, and a first front bonding structure along a frontside surface of the first memory wafer, wherein the first memory wafer comprises a first memory die;
flipping and bonding the first memory wafer to the logic wafer, wherein the first front bonding structure of the first memory wafer is bonded to the front bonding structure of the logic wafer; and
removing the first substrate and the first sacrificial dielectric layer from the first memory wafer to expose the first buried bonding structure from a backside surface of the first memory wafer.

2. The method of claim 1, wherein the bonding structure of the logic wafer comprises a bonding dielectric layer and a plurality of bonding conductors embedded within the bonding dielectric layer.

3. The method of claim 1, wherein the first buried bonding structure of the first memory wafer comprises a first buried bonding dielectric layer and a plurality of first buried bonding conductors embedded within the first bonding dielectric layer.

4. The method of claim 1, wherein coefficients of thermal expansion (CTEs) of the first substrate and the first sacrificial dielectric layer of the first memory wafer are different from coefficients of thermal expansion (CTEs) of the first buried bonding dielectric layer and the plurality of first buried bonding conductors of the first buried bonding structure of the first memory wafer.

5. The method of claim 1, wherein the first substrate and the first sacrificial dielectric layer are removed from the first memory wafer by at least a laser lift-off process.

6. The method of claim 1, further comprising:
forming a second memory wafer comprising a second sacrificial dielectric layer over a second substrate, a second buried bonding structure over the second sacrificial dielectric layer, and a second front bonding structure over the second buried bonding structure and along a frontside surface of the second memory wafer, wherein the second memory wafer comprises a second memory wafer;
flipping and bonding the second memory wafer to the first memory wafer, wherein the second front bonding structure of the second memory wafer is bonded to the first buried bonding structure of the first memory wafer; and
removing the second substrate and the second sacrificial dielectric layer from the second memory wafer by another laser lift-off process to expose the second buried bonding structure from a backside surface of the second memory wafer.

7. The method of claim 1, wherein the first memory wafer further comprises a first pair of redistribution layers (RDLs) within a first interlayer dielectric (ILD) over the first buried bonding structure, and one or more layers of first memory cells vertically between the first pair of RDLs.

8. The method of claim 7, wherein one of the first memory cells is selected from a group consisting of a 1-Transistor 1-Capacitor (1T1C) Dynamic Random Access Memory (DRAM), a 2T (2-Transistor) DRAM, a 1-Transistor 1-Resistor (1T1R) Resistive Random Access Memory (RRAM), a 1T1C Ferroelectric Random Access Memory (FeRAM), and a 1-Transistor 1-Magnetic Tunnel Junction (1T1MTJ) Magnetoresistive Random Access Memory (MRAM).

9. A method of manufacturing a three-dimensional integrated circuit package, comprising:
providing a first memory wafer comprising a first sacrificial dielectric layer over a first substrate;
forming a first etch stop layer on the first sacrificial dielectric layer;
forming a first buried dielectric layer on the first etch stop layer;
forming a plurality of first buried bonding conductors embedded within the first buried bonding dielectric layer to create a first buried bonding structure;
forming a first interlayer dielectric (ILD) layer over the first buried bonding structure; and
forming a first front bonding structure along a frontside surface of the first memory wafer, wherein the first front bonding structure comprises a first front bonding dielectric layer over the first buried bonding dielectric layer and a plurality of first front bonding conductors embedded within the first front bonding dielectric layer.

10. The method of claim 9, further comprising:
flipping and bonding the first memory wafer to a logic wafer; and
removing the first semiconductor substrate and the first sacrificial dielectric layer from the first memory wafer.

11. The method of claim 10, wherein the first substrate and the first sacrificial dielectric layer are removed from the first memory wafer by a laser lift-off process.

12. The method of claim 10, further comprising:
providing a second memory wafer comprising a second sacrificial dielectric layer over a second substrate, wherein the second memory wafer comprises a second memory wafer;
forming a second etch stop layer on the second sacrificial dielectric layer;
forming a second buried dielectric layer on the second etch stop layer;
forming a plurality of second buried bonding conductors embedded within the second buried bonding dielectric layer to create a second buried bonding structure;
forming a second interlayer dielectric (ILD) layer over the second buried bonding structure; and
forming a second front bonding structure along a frontside surface of the second memory wafer, wherein the second front bonding structure comprises a second front bonding dielectric layer over the second buried bonding dielectric layer and a plurality of second front bonding conductors embedded within the second front bonding dielectric layer.

13. The method of claim 12, further comprising:
flipping and bonding the second memory wafer to the first memory wafer; and
removing the second semiconductor substrate and the second sacrificial dielectric layer from the second memory wafer by a laser lift-off process.

14. The method of claim 9, further comprising:
post forming the first ILD layer over the first buried bonding structure, forming a first redistribution layer (RDL) within the first ILD layer;
forming one or more layers of first memory cells over the first RDL within the first ILD layer; and
forming a second RDL within the first ILD layer over the one or more layers of first memory cells.

15-20. (canceled)

21. A stack of memory dies, comprising:
a first memory die comprising a first bonding structure along a frontside surface of the first memory die and a second bonding structure along a backside surface of the first memory die,
wherein the first bonding structure comprises a first dielectric bonding layer and a plurality of first conductive bonding pads coplanar with the first dielectric bonding layer along the frontside surface of the first memory die,
wherein the second bonding structure comprises a second dielectric bonding layer and a plurality of second conductive bonding pads coplanar with the second dielectric bonding layer along the backside surface of the second memory die, and
wherein the plurality of first conductive bonding pads and the plurality of second conductive bonding pads are each tapered in a same vertical direction from the frontside surface of the first memory die to the backside surface of the first memory die.

22. The stack of memory dies of claim 21, further comprising:
a second memory die stacked on the first memory die, and comprising a third bonding structure along a frontside surface of the second memory die and a fourth bonding structure along a backside surface of the second memory die,
wherein the third bonding structure comprises a third dielectric bonding layer and a plurality of third conductive bonding pads coplanar with the third dielectric bonding layer along the frontside surface of the second memory die,
wherein the fourth bonding structure comprises a fourth dielectric bonding layer and a plurality of fourth conductive bonding pads coplanar with the fourth dielectric bonding layer along the backside surface of the second memory die, and
wherein the plurality of third conductive bonding pads and the plurality of fourth conductive bonding pads are each tapered in a same vertical direction from the frontside surface of the second memory die to the backside surface of the second memory die.

23. The stack of memory dies of claim 22, wherein the second bonding structure of the first memory die and the third bonding structure of the second memory die are bonded along a planar interface.

24. The stack of memory dies of claim 23,
wherein the second dielectric bonding layer of the second bonding structure of the first memory die and the third dielectric bonding layer of the third bonding structure of the second memory die are bonded along the planar interface, and
wherein the plurality of second conductive bonding pads of the second bonding structure of the first memory die and the plurality of third conductive bonding pads of the third bonding structure of the second memory die are respectively bonded along the planar interface.

25. The stack of memory dies of claim 22, wherein the first memory die further comprises a plurality layers of first memory cells disposed vertically between the first bonding structure and the second bonding structure, and coupled to at least one of the first bonding structure and the second bonding structure.

26. The stack of memory dies of claim 22, wherein the second memory die further comprises a plurality layers of second memory cells disposed vertically between the third bonding structure and the fourth bonding structure, and coupled to at least one of the third bonding structure and the fourth bonding structure.
